(19) United States
(12) Patent Application Publication
(10) Pub. No.: US 2017/0315646 A1
(43) Pub. Date: Nov. 2, 2017

(54) CAPACITIVE CONTROL INTERFACE DEVICE INTEGRATED WITH A DISPLAY SCREEN

(71) Applicant: QUICKSTEP TECHNOLOGIES LLC, Wilmington, DE (US)

(72) Inventor: Didier ROZIERE, Nimes (FR)

(73) Assignee: QUICKSTEP TECHNOLOGIES LLC, Wilmington, DE (US)

(21) Appl. No.: 15/522,746

(22) PCT Filed: Jun. 19, 2015
(86) PCT No.: PCT/EP2015/063857

§ 371 Date: Apr. 27, 2017

(30) Foreign Application Priority Data
Oct. 29, 2014 (FR) 1460381

(51) Int. Cl. G06F 3/041; G02F 1/1333; G06F 3/044; H01L 27/32; G02F 1/1343; G02F 1/1368

(52) U.S. Cl. CPC G06F 3/0412; G06F 3/044; G02F 1/13338; H01L 27/323; G02F 1/134363; G06F 2203/04107; G02F 1/1368; H01L 27/3244

(57) ABSTRACT

The present invention relates to a man-machine interface device comprising (i) a display with display pixels distributed within a display zone, (ii) display control elements (302, 304) disposed in said display zone and used to control said display pixels, (iii) capacitive measurement electrodes (502) distributed within said display zone, (iv) capacitive excitation and detection means, (v) at least one guard element disposed in proximity to the capacitive measurement electrodes (502), in which at least one display control element (302, 304) is also used as guard element or as capacitive measurement electrode (502). The invention also relates to an apparatus comprising the device.

### TECHNICAL DOMAIN

This invention relates to a capacitive command interface mechanism incorporated in a display screen. It also relates to a device comprising such a mechanism.

The domain of the invention is more specifically, but without limitation, that of human-machine interface mechanisms and systems.

### STATE OF THE PRIOR ART

Many devices, such as for example telephones, smart phones or tablets are equipped with a command interface in the form of a touchscreen.

In general, these touchscreens are made in the form of a display screen on top of which are superposed a capacitive touchpad and protective glass.

For miniaturized devices, especially smart phone or tablet type, the display screen conventionally uses:
technologies based on liquid crystals, with in particular liquid crystal displays (LCD), or
technologies based on organic light-emitting diodes (OLED), including in particular active matrix organic light-emitting diodes (AMOLED) displays.

Screens based on liquid crystals (LCD) implemented in current devices are often based on an active-matrix based technology. They can in particular include the following layers, from the base towards the viewing surface (which faces the user):
a backlighting layer (for example with white light-emitting diodes);
a command layer with at least partially transparent thin film transistors (TFT);
command electrodes of the pixels,
a liquid crystal layer;
a conducting layer, or shared potential layer, polarized to a reference potential and often called common electrode or Vcom;
a filtering layer with colored filters corresponding to the primary colors,
a polarization layer with a polarizing element.

With the TFT transistors, a voltage (relative to Vcom) can be selectively applied through the liquid crystal layer such that the orientation of the liquid crystals changes locally. In this way, the light coming from the backlighting layer which passes through them is transmitted or blocked by the polarization layer based on the polarization of the light on leaving the liquid crystal layer.

In variants on LCD technology, the state of the liquid crystals is controlled by command electrodes located in a single plane. These techniques are called in-plane switching (IPS). Other variations of these techniques called “in-plane switching” are known as “Advanced IPS”, AH-IPS, FFS (“Field Fringe Switching”), etc.

In this case, the common potential layer, Vcom, can be between the command layer with the TFT transistors and a layer with the command electrodes.

Screens based on organic light-emitting diodes (AMOLED) can include the following layers, from the base towards the viewing surface (which faces the user):
a command layer with thin-film transistors (TFT);
an organic matrix layer forming the light-emitting diodes respectively emitting a primary color;
a conducting layer, or shared potential layer, polarized to a reference potential and often called cathode;

The TFT transistors make it possible to pass a current through the light-emitting diodes in order to selectively light them.

Capacitive touchpads generally implement a detection technique based either on a measurement of mutual-capacitance (mutual-capacitance or mutual) or on a direct capacitance measurement (self-capacitance or self).

The techniques for measuring mutual capacitance are the ones which are most commonly used for touch interfaces. They implement electrodes for excitation and electrodes for measuring capacitive coupling between them. When a command object (for example a finger) is near an area of coupling between excitation and measurement electrodes, the object changes the capacitive coupling between these electrodes which allows for detecting the object.

The “self” type measurement techniques are based on a direct measurement of the capacitance which is established between capacitance measurement-electrodes and a nearby command object. They have the advantage of allowing detection of objects at larger distance and in that way allowing the implementation of a command interface sensitive to objects that are no longer solely in contact with the detection surface, but also nearby. In this way touch and contactless interfaces can be implemented.

However, the capacitances to be measured are very small and avoiding parasitic capacitive coupling between the measurement electrodes and their environment is imperative. In order to do that, it is known to implement an active guard. Conducting surfaces described as “guard” are added between the measurement electrodes and the disrupting elements (including the display screen placed underneath). The electrodes and the guard are excited at an alternating voltage, described as guard, similarly, which blocks the appearance of leakage capacitances between them.

“Self” type capacitance measurement techniques are also known in which the detection electronics is also referenced to the guard potential, which serves to minimize leakage capacitances. This type of detection electronics, referred to as “floating reference” or “floating bridge”, is in particular described in detail in the Rozière patent FR 2,756,048.

Display screens and touchpads are made by depositing materials on dielectric substrates, which results in a stacking of layers. For example, the conducting surfaces or traces can be made by depositing a substantially transparent material such as ITO (indium-tin oxide), and the TFT transistors are made according to planar techniques.

The implementation of a touchscreen by simple stacking of a display screen and a capacitive touchpad has disadvantages, including:
an excessive thickness for some devices such as smart phones;
a degradation of the visual quality of the image because of the thickness of the touchscreen;
an high cost because of the presence of 2 independent systems.

It is therefore desirable to improve the integration of the functions of the pad and display screen.

Techniques are known which consist of depositing capacitive electrodes directly on the surface of the display screen. These techniques are often designated under the name “on-cell”. Crossed excitation and measurement electrodes, respectively in rows and columns, are deposited either on a single layer with a bridge for each intersection or else on 2 distinct layers. The measurements are performed according to mutual capacitance measurement techniques.

Techniques are also known which consist of using electrical circuits or electrodes for the display screen in order to implement a portion of the electrodes for the capacitive sensor. These technologies are in general designated under the name “in-cell”. Techniques are known in particular which implement mutual capacitance measurements (“mutual” mode), with excitation electrodes implemented in the common potential Vcom layer of a TFT type display screen and measurement electrodes implemented on the surface of this display screen.

With known “in-cell” type technologies it is not in particular possible to detect distant command objects according to the performance achievable with “self” type techniques with a guard.

The purpose of the present invention is to propose a touchscreen type command interface mechanism with optimized thickness, integration cost and/or image quality.

The purpose of the present invention is to propose a touchscreen type command interface mechanism with a capacitive sensor essentially integrated into the display screen according to an in-cell type technique.

The purpose of the present invention is also to propose such an interface mechanism serving to detect command objects at a distance, without contact.

### DESCRIPTION OF THE INVENTION

This objective is achieved with a human-machine interface mechanism comprising:
a display with display pixels distributed in a display area;
display control elements arranged in said display area and used for controlling said display pixels;
capacitance measurement-electrodes distributed in said display area;
capacitive means of excitation and detection suited for (i) exciting the capacitance measurement-electrodes to an alternating electric excitation potential relative to a bulk ground with at least one excitation frequency; and (ii) detecting the presence of command objects in a neighborhood of said capacitance measurement-electrodes on one surface of the display referred to as “viewing surface”, by capacitive coupling between said capacitance measurement-electrodes and the one or more command objects; and
at least one guard element arranged near capacitance measurement-electrodes and polarized to a guard potential identical or substantially identical to the excitation potential at the one or more excitation frequencies;

The mechanism is characterized in that at least one display control element is also used as a guard element or as a capacitance measurement-electrode.

The display pixels can be display points which make up the image.

The display control elements can in particular include electrodes, transistors, etc. which serve to control the display pixels.

The capacitance measurement-electrodes, the capacitive means of detection and the one or more guard elements can in that way constitute a capacitance measurement interface with which to detect with high sensitivity, at a distance or in contact with the viewing surface, one or a plurality of command objects (for example, finger or stylus type).

The measurement of the coupling capacitance or the capacitive coupling between command objects and capacitance measurement-electrodes can serve to obtain location information (out of plane distance Z and position in the X, Y plane relative to the viewing surface) of these objects.

As the electrodes are polarized to an alternating electrical potential for excitation, and as the objects can be considered as electrically referenced to a bulk electrical ground of the system, this measurement of the capacitive coupling can be done at one or more measurement frequencies corresponding to excitation frequencies of the electric potential (for example by using synchronous detection).

The guard elements serve to minimize the leakage capacitances between the capacitance measurement-electrodes and their environment, which makes it possible to optimize the detection sensitivity. In order to do that, they must be polarized to a guard potential identical or substantially identical to the excitation potential in order that leakage capacitances not appear between them and the capacitance measurement-electrodes.

Just the same it has to be noted that to the extent where the capacitive detection is done at one or more measurement frequencies corresponding to electric potential excitation frequencies, the guard elements can be polarized at electric potentials which include other components, in particular frequency (e.g. DC, high-frequency signals, etc.), so long as these components do not make a contribution to the one or more measurement frequencies. This condition can be satisfied for example when these additional components are orthogonal, in the scalar product meaning, to the electrical potential for excitation or in some cases when they are synchronous with the excitation potential with transitions away from the instant of measurement of the capacitive signals.

In particular, the guard elements may be polarized at electric potentials that comprise a direct current (DC) component, since its contribution is null or negligible at the measuring frequency.

The measurement electrodes can advantageously be laid out according to a matrix arrangement. This allows in particular simultaneously and unambiguously detecting, including remotely, several command objects.

According to an advantageous aspect of the invention, this capacitance measurement interface is incorporated into the display screen in in-cell or on-cell mode because it has elements in common with this display screen.

Depending on the embodiments of the mechanism according to the invention, at least a portion of the display and/or display control elements can be electrically referenced to a reference potential corresponding to the guard potential, at least during the capacitance measurement phase.

In that way, when the display or at least the electronic or conducting elements thereof (e.g. transistors, electrodes, etc.) are at least in part referenced to the guard potential, they additionally contribute to the guard and to the protection of the electrodes against the external elements. It can then be considered that they make up part of the guard elements.

As previously explained, the presence in the electronic elements of the display of electric potentials or voltages different from the guard potential, which is inevitable during their use, does not disrupt the effectiveness of the guard, so long as they do not generate parasitic components at the guard potential frequencies used for the capacitance measurement.

Depending on the embodiments, the operation of the mechanism can include capacitance measurement phases for detecting command objects which alternate with display phases for refreshing the displayed image. In this case, the minimization of the leakage capacitances is important during the capacitance measurement phases.

Just the same, this operation by alternated phases of capacitance measurement and display is often not indispensable in the context of the invention, in so far as the capacitance measurement-electrodes are effectively protected by the guard elements.

Depending on the embodiments, the mechanism according to the invention can include capacitance measurement-electrodes incorporated in a layer, referred to as “upper layer of capacitive electrodes”, arranged towards the viewing surface relative to the constituent layers of the display pixels. In this case, the mechanism according to the invention corresponds to an on-cell configuration.

This upper layer of capacitive electrodes can for example be implemented by a deposit of transparent conducting material such as ITO or nano-wires on the outer surface of the display under a protective glass.

The mechanism according to the invention can include guard elements integrated into a layer of display control elements, called “common potential layer”, shared with at least one part of the display pixels.

This common potential layer can for example be the Vcom layer of an LCD type display, or the common cathode of an OLED type display.

It should be noted that if the display control elements, including this common potential layer, are referenced to the guard potential as previously described, this common potential layer is naturally a guard element, even without making changes to it compared to the function thereof for the display.

Depending on the embodiment, the mechanism according to the invention can include capacitance measurement-electrodes integrated into a layer of display control elements, called “common potential layer”, shared with at least one part of the display pixels.

In this case, the mechanism according to the invention corresponds to an in-cell configuration.

As before, this common potential layer can for example be the Vcom layer of an LCD type display, or the common cathode of an OLED type display.

The mechanism according to the invention may include a common potential layer arranged in the form of an electrode matrix, and means of switching with which to connect these electrodes either to capacitive means of detection or to a reference potential, at least during a capacitance measurement phase.

The mechanism according to the invention can additionally include a layer of guard elements, called “lower guard layer”, arranged opposite the viewing surface relative to the constituent layers of the display pixels.

This lower guard layer is intended to avoid capacitive coupling between the measurement electrodes and elements located under the display.

Depending on the embodiments, the mechanism according to the invention can include a display with liquid crystal elements.

It can in particular include a common potential layer with capacitance measurement-electrodes and a command layer with transistors suited for controlling the liquid crystal elements arranged opposite the common potential layer relative to the viewing surface.

These transistors may be TFT (thin-film transistors).

It should be noted that if the command layer with the transistors is at least in part referenced to the guard potential, then it additionally contributes to the guard and to the protection of the electrodes against external elements. It can then be considered that this control layer is part of the guard elements.

Depending on the embodiments implementing an IPS type display with command electrodes for the liquid crystal elements arranged in a plane towards the viewing surface relative to the common potential layer, the mechanism according to the invention can furthermore include means of switching with which to electrically isolate the command electrodes, such that they are electrically floating during capacitance measurements.

In fact, in this case the command electrodes are located between the capacitance measurement-electrodes and the command objects to be detected. If they are isolated, they will simply be held at the “ambient” electrical potential and in that way will not generate leakage capacitances.

Depending on the embodiments, the mechanism according to the invention can include a display with organic light-emitting diodes (OLED).

It can in particular include a common potential layer, or common cathode, with capacitance measurement electrodes and a command layer with transistors suited for controlling the organic light-emitting diodes arranged opposite the common potential layer relative to the viewing surface.

Just as before, it should be noted that if the command layer with the transistors is at least in part referenced to the guard potential, then it additionally contributes to the guard and to the protection of the electrodes against external elements. It can then be considered that this control layer is part of the guard elements.

Depending on the embodiments, the mechanism according to the invention can comprise capacitance measurement-electrodes with openings across from the command layer transistors, so as to limit the coupling capacitances between these elements.

In fact, even in the case where the command layer is referenced to the guard potential, it is desirable to limit the capacitance between the measurement electrodes and the guard elements, because if this capacitance does not generate leakage capacitance it just the same loads the input stage of the detection electronics unnecessarily.

Depending on the embodiments, the mechanism according to the invention can comprise a lower guard layer arranged across from the command layer relative to the viewing surface.

With this lower guard layer, capacitive coupling between the measurement electrodes and the elements located under the display can be avoided or at least the guard already obtained with the command layer referenced to the guard potential can be improved.

Depending on the embodiments, the mechanism according to the invention may comprise capacitive detection means with at least one charge amplifier.

The capacitive detection means may further comprise switches arranged so as to connect, at least during a capacitance measurement phase, the capacitance measurement electrodes either to a charge amplifier, or to the guard potential.

Depending on the embodiments, the capacitive detection means may comprise a charge amplifier referenced to the bulk ground.

According to other embodiments, the capacitive detection means can be referenced at least in part to the guard potential.

In that way, when the sensitive part (in particular) of the capacitive detection means is referenced to the guard potential, leakage capacitances are avoided in the area of the input stages of the detection electronics (for example a charge amplifier) of the embodiments of the device.

Depending on the embodiments, the mechanism according to the invention may comprise display control electronics referenced to the bulk ground, and a switching module making it possible to configure display control elements positioned in the display zone, including at least one command layer and one common potential layer, such that said display control elements are referenced to:
the bulk ground during the refresh phases of the display;
the guard potential, directly or by capacitive coupling, during the capacitance measurement phases.

The display control electronics may be an integrated circuit.

Depending on the embodiments, the switching module may comprise:
data switches arranged so as to connect data lines of the display pixels, either to the display control electronics, or to the guard potential;
control switches arranged so as to connect control lines of the display pixels, either to the display control electronics, or to a direct potential referenced to the guard potential and serving to keep pixel control transistors blocked.

Depending on the embodiments, the switching module may comprise:
data switches arranged so as to connect data lines for the display pixels, either to the display control electronics, or to the guard potential;
command switches arranged so as to connect command lines of the display pixels to the display control electronics, or to keep said control lines electrically floating.

Depending on the embodiments, the switching module may comprise:
data switches arranged so as to connect data lines of the display pixels to the display control electronics, or to keep said data lines electrically floating,
command switches arranged so as to connect command lines of the display pixels to the display control electronics, or to keep said control lines electrically floating.

Depending on the embodiments, the switching module may further comprise at least one reference switch arranged so as to connect the common potential layer, either to a common potential Vcom or cathode of the display screen referenced to the bulk ground, or to the guard potential.

Depending on the embodiments of a mechanism comprising capacitance measurement electrodes integrated into the common potential layer, the switching module may further comprise electrode switches arranged so as to respectively connect the measurement electrodes, either to the capacitance measurement electronics, or to a common potential Vcom or cathode of the display screen referenced to the bulk ground.

The switching module may in particular include electrode switches comprising:
a first electrode switch arranged so as to connect a measuring electrode, either to the capacitance measurement electronics, or to a second electrode switch;
a second electrode switch arranged so as to connect said first electrode switch either to a common potential Vcom or cathode of the display screen referenced to the bulk ground, or to the guard potential.

Depending on the embodiments of a mechanism comprising a display with organic light-emitting diodes (OLED), the mechanism according to the invention further comprises a power source for the OLEDs connected at output to the power lines of said organic light-emitting diodes, said power source of the OLEDs being electrically floating and referenced to the potential of the common potential layer.

Depending on the embodiments, the mechanism according to the invention may comprise switches made with:
transistors of one of the following types: FET, OFET, MOS, MOSFET, TFT;
transistors controlled by a gate signal referenced to the bulk ground;
transistors controlled by a gate signal referenced to the guard potential;
TFT transistors localized in or on the border of the display zone.

According to another aspect, a device comprising a human-machine interface mechanism according to the invention is proposed.

In particular, this device can be one of the following types: telephone, smart phone, tablet, display screen and computer.

### DESCRIPTION OF FIGURES AND EMBODIMENTS

Other advantages and specificities of the invention will appear to the reader from the detailed description of implementations and embodiments, which are in no way limiting, and from the following attached drawings:

FIG. 1 shows an example of a touchscreen type human-machine interface from the prior art.

FIG. 2 shows an example of a display screen of the active-matrix LCD type from the prior art,

FIG. 3 shows an example of an IPS technology LCD type display screen from the prior art,

FIG. 4 shows an example of an AMOLED type display screen from the prior art,

FIG. 5 shows a first embodiment of the on-cell type invention according to a variant integrated into an active matrix LCD type display screen,

FIG. 6 shows a first embodiment of the on-cell type invention according to a variant integrated into an IPS technology LCD type display screen,

FIG. 7 shows a first embodiment of the on-cell type invention according to a variant integrated into an AMOLED-type LCD display screen,

FIG. 8 shows a second embodiment of the in-cell type invention according to a variant integrated into an active matrix LCD type display screen,

FIG. 9 shows a second embodiment of the in-cell type invention according to a variant integrated into an IPS technology LCD type display screen,

FIG. 10 shows a second embodiment of the in-cell type invention according to a variant integrated into an AMOLED type LCD display screen,

FIG. 11 shows an overview drawing of the control electronics for the first on-cell embodiment of the invention,

FIG. 12 shows an overview drawing of the control electronics for the second in-cell embodiment of the invention,

FIG. 13 shows an example schematic drawing of control electronics for an LCD technology pixel,

FIG. 14 shows an example schematic drawing of control electronics for an AMOLED technology pixel,

FIG. 15 shows an example embodiment of active guard capacitive detection electronics,

FIG. 16 shows an example embodiment of active guard capacitive detection electronics and floating electronics,

FIG. 17 illustrates an example arrangement of a mechanism according to the invention,

FIG. 18 shows an overview drawing of the control electronics for the first on-cell embodiment of the invention with display control electronics referenced to the bulk ground,

FIG. 19 shows an overview drawing of the control electronics for the first in-cell embodiment of the invention with display control electronics referenced to the bulk ground,

FIG. 20 illustrates a control electronics implementation mode for the first on-cell embodiment of the invention for LCD screens with display control electronics at the bulk ground,

FIG. 21 illustrates a control electronics implementation mode for the first on-cell embodiment of the invention for OLED screens with display control electronics at the bulk ground,

FIG. 22 illustrates a control electronics implementation for the first in-cell embodiment of the invention for LCD screens with display control electronics at the bulk ground,

FIG. 23 illustrates a control electronics implementation mode for the first in-cell embodiment of the invention for OLED screens with display control electronics at the bulk ground.

It is clearly understood that the embodiments which will be described in the following are in no way limiting. One could in particular imagine variants of the invention comprising only a selection of features subsequently described isolated from other features described if this selection of features is sufficient for conferring a technical advantage or distinguishing the invention compared to the prior state of the art. This selection includes at least one preferably functional feature without structural details or with only a part of the structural details if this part alone is sufficient for conferring a technical advantage or distinguishing the invention compared to the prior state-of-the-art.

In particular all the variants and all the embodiments described are mutually combinable if nothing at a technical level prevents that combination.

In the figures, the elements shared by several figures retain the same reference.

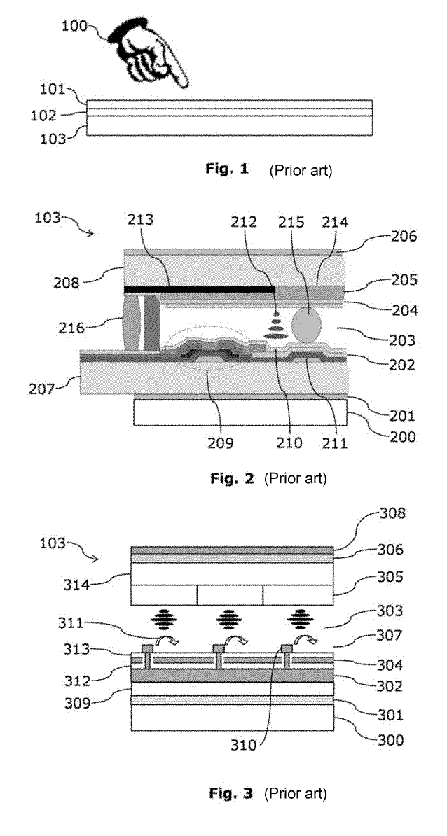

First, with reference to FIG. 1, a touchscreen type human-machine interface mechanism representative of the state-of-the-art is going to be described. Such a touchscreen conventionally includes:
a display screen 103, with, for example, a matrix of liquid crystal pixels (liquid crystal display, LCD, type display) or a matrix of organic light-emitting diodes (active matrix organic light-emitting diodes, AMOLED, type display);
a capacitive panel 102 with capacitance measurement-electrodes serving to detect by capacitive coupling the proximity and/or contact of a command object 10 such as a finger;
a protective glass 101.

The display screen 103 and the capacitive panel 102 are made in the form of distinct subsystems assembled by stacking.

As brought up previously, such an embodiment has disadvantages such as an excessive thickness and degradation of the image quality.

FIGS. 2, 3 and 4 show examples of display screen 103 technologies from the prior art currently implemented in touchscreens such as shown in FIG. 1. These examples of display technologies have been chosen to serve as a base for the description of embodiments of the invention, but of course the invention is in no case limited to these particular display embodiments.

In order to be clear and concise, in so far as it involves well-known technologies, their representations and their descriptions are limited to the elements essential and necessary to the understanding of the invention.

The breakdown in terms of layers (e.g. command layer, common potential layer, etc.) that is used in the description is an essentially functional breakdown adopted for clarity reasons. Of course, these (functional) layers do not necessarily strictly correspond to the stacks of physical layers of materials (e.g. ITO, insulator, substrate, transistors, etc.). Thus, for example:
a functional layer may comprise several layers of materials (e.g. ITO, insulator, substrate, transistors, etc.),
adjacent functional layers may comprise common or inter-penetrating zones, or even be partially or completely combined in the thickness of the display.

FIG. 2 shows a sample display screen 103 embodiment using an active matrix liquid crystal technology (AMLCD). The portion shown corresponds to one display pixel (or one sub-pixel corresponding to a primary color).

In the embodiment shown, the display screen 103 in particular includes the following successive elements:
a backlighting layer 200, for example based on light-emitting diodes;
a lower polarizer layer 201 located facing the backlighting layer 200. This polarizer layer 201 may be omitted based on the polarization of the incident light;
a command layer 202 which includes in particular TFT transistors 209, command electrodes 210 driven by the transistors 209, and storage capacitor electrodes 211 for which the second electrode is at the potential of the common potential layer. This command layer 202 is implemented on a dielectric substrate 207, for example glass;
a liquid crystal layer 203, held by spacers 215 and sealing elements 216, and which contains liquid crystals 212;
a common potential layer 204, often called Vcom;
a filtering layer 205, with colored filters 214 corresponding to the primary colors arranged on the substrate 208 and opaque masking elements 213 facing the transistors 209;
an upper polarizer layer 206.

The transparent conducting elements, including the command electrodes 210 and the common potential layer 204 Vcom, are made by depositing ITO.

The TFT transistors 209 serve to control the lighting and darkening of the pixels by controlling the voltage applied through the liquid crystal layer 203 between the command electrodes 210 and the common potential layer Vcom 204. These transistors 209 are distributed according to a matrix arrangement in order to control all the pixels, and they are driven via electric data and command traces arranged in rows and columns so as to address each one of them.

Depending on the voltage applied to the command electrodes 210 by the TFT transistors 209, the liquid crystals 212 adopt a different orientation and change the orientation of the polarization of the incident light, polarized by the lower polarizer 201. According to the resulting polarization, the light is or is not blocked by the upper polarizer 206.

The storage capacitors 211 serve to maintain a given voltage proportional to the desired light intensity between the activation phases of the transistors 209.

FIG. 3 shows a sample liquid crystal display screen 103 embodiment using IPS type technology. The portion shown corresponds to 3 pixels, or 3 sub-pixels of a primary color.

IPS type technologies (there are several variants), in particular including technologies of the FFS (Fringe Field Switching) type, serve to correct defects of conventional LCD type technologies, including narrow viewing angles and imprecise colors. In an IPS type display screen, the 2 electrodes (for command and at the common potential) which command the pixels are placed on the same side of the liquid crystal layer instead of being placed on both sides of this liquid crystal layer. In that way, instead of swinging between a position perpendicular to the plane of the display and a position parallel to this plane, the liquid crystals remain continuously in a plane parallel to the plane of the display (hence the name of the technology: In-Plane Switching), by turning on themselves in this plane.

In the embodiment shown, the display screen 103 in particular includes the following successive elements:
a backlighting layer 300, for example based on light-emitting diodes;
a lower polarizer layer 301 located facing the backlighting layer 300. This polarizer layer 301 may be omitted based on the polarization of the incident light;
a command layer 302 with in particular thin-film technology (TFT) transistors implemented on a substrate 309;
a common potential layer 304, often called Vcom;
a control electrode layer 307, with command electrodes 310;
a first electrically insulating layer 312 placed between the command layer 302 and the common potential layer 304;
a second electrically insulating layer 313 placed between the control layer 304 and the electrode layer 307;
a liquid crystal layer 303;
a filtering layer 305 with colored filters corresponding to the primary colors deposited on a substrate 314;
an upper polarizer layer 306;
an antistatic conducting layer 308, in order to protect the assembly from electrostatic discharges.

This liquid crystal display technology therefore differs from that from FIG. 2 essentially by the fact that the orientation of the liquid crystals is managed by an electric field 311 generated between the command electrode 310 and the common potential layer 304 located on the same side of the liquid crystal layer 303.

In particular, the pixels are driven by TFT transistors from the command layer 302 in a manner similar to what is described in relation with FIG. 2.

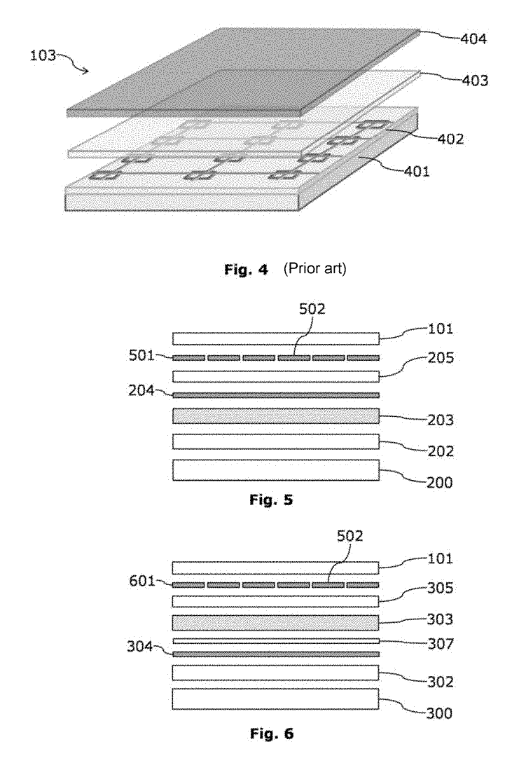

FIG. 4 shows a sample display screen 103 embodiment according to an active matrix organic light-emitting diode (AMOLED) based technology.

According to this technology, the display screen 103 in particular comprises the following successive elements:
a command layer 402 with in particular thin-film technology (TFT) transistors. This command layer 402 is implemented on a dielectric substrate 401, for example glass;
a layer of organic materials 403 arranged in stack form in order to build up junctions of light-emitting diodes;
a common potential layer 404, often called cathode (or sometimes common electrode, or even anode) in this technology.

In this technology, the organic materials layer 403 makes up a set of light-emitting diodes respectively connected to command electrodes controlled by TFT transistors from the command layer 402 and to the common potential layer 404 which constitutes a common cathode.

The TFT transistors in that way serve to control the lighting and darkening of pixels by controlling the current applied towards the cathode 404 through the light-emitting diodes constituting the organic materials layer 403. These TFT transistors are distributed according to a matrix arrangement in order to control all the pixels, and they are driven via electric data and command traces arranged in rows and columns so as to address each one of them.

Embodiment of On-Cell Type Interface Mechanism

A first embodiment of the interface mechanisms according to the invention is now going to be described with reference to FIGS. 5, 6 and 7 in variants incorporated respectively in:
an active matrix LCD type display screen (FIG. 5);
an LCD type display screen with IPS technology (FIG. 6);
an AMOLED type display screen (FIG. 7).

The display screen technologies implemented in these various implementations are described in detail in connection with FIGS. 2, 3 and 4, respectively. Also, in order to be clear and concise, they are only shown in a schematic form of superposed layers in FIGS. 5, 6 and 7.

In this embodiment, the interface mechanism according to the invention includes capacitance measurement-electrodes incorporated in a layer, referred to as “upper layer of capacitive electrodes”, arranged towards the viewing surface relative to the constituent layers of the display pixels. This embodiment is therefore of the on-cell type.

The viewing surface is constituted for example by a protective glass. The constituent layers of the display pixels are layers which enable their operation. They can for example include the liquid crystal layer, or the organic material layer according to the display technology considered.

In these embodiments, the interface mechanism according to the invention also comprises guard elements integrated into the common potential layer.

As previously explained, the capacitance measurement-electrodes are excited to an excitation electrical potential and the guard elements must be polarized to a guard potential identical or substantially identical to the excitation potential at least at measurement frequencies corresponding to the frequencies of the excitation electrical potential in order to be effective. In order to do that, the following configurations are possible in the context of the invention.

According to a first configuration, the display control electronics (including for example the TFT transistors) are referenced to a potential different from the guard potential, such as for example a bulk ground potential of the device. In this case, in order to perform the capacitance measurements it is necessary to switch (with switches for example) the common potential layer to the guard potential during capacitance measurements. That implies that measuring the capacitances and refreshing the display are done sequentially during different temporal periods. This sequential operation can be done over the entirety of the display or around portions of the display.

According to one preferred configuration, the display control electronics (including for example the TFT transistors) are referenced to the guard potential. In this case, the common potential layer of the display and additionally also other elements (for example the command layer) are naturally part of or comprise elements of the guard.

In that way, a very effective guard results. Furthermore, the capacitance measurements and the refresh operations of the display can be executed simultaneously because they do not interfere and do not require a reconfiguration of the electronics. It is simply preferable to perform these operations synchronously by taking the precaution of avoiding the appearance of transients at critical or sensitive moments of one or the other of the processes of measurement and display.

FIG. 5 shows a first interface mechanism embodiment according to the invention in a variant integrated into an active matrix LCD type display screen. As previously explained, the mechanism shown in FIG. 5 corresponds to a schematic representation of the display shown in FIG. 2, modified according to the invention.

In the embodiment shown, the interface mechanism includes in particular the following successive elements:
a backlighting layer 200, for example based on light-emitting diodes;
a lower polarizer layer (not shown). This polarizer layer may be omitted based on the polarization of the incident light;
a command layer 202 which comprises in particular thin-film technology (TFT) transistors and command electrodes;
a liquid crystal layer 203;
a common potential layer 204, also used as guard element;
a filtering layer 205, with color filters deposited on a substrate;
an upper polarizer layer (not shown);
an upper capacitive electrode layer 501, with a matrix of capacitance measurement-electrodes 502;
protective glass 101.

The capacitive electrode layer 501 is implemented with a deposit of transparent conducting material, such as ITO or nanowires, on a dielectric surface In the embodiment shown, it is deposited on the substrate which supports the color filters. It comprises capacitive electrodes 502 distributed on the display surface according to a matrix arrangement.

FIG. 6 shows the first interface mechanism embodiment according to the invention in a variant integrated into an LCD type display screen with IPS technology. As previously explained, the mechanism shown in FIG. 6 corresponds to a schematic representation of the display shown in FIG. 3, modified according to the invention.

In the embodiment shown, the interface mechanism includes in particular the following successive elements:
a backlighting layer 300, for example based on light-emitting diodes;
a lower polarizer layer (not shown). This polarizer layer may be omitted based on the polarization of the incident light;
a command layer 302 which comprises in particular thin-film technology (TFT) transistors;
a common potential layer 304, also used as guard element;
a control electrode layer 307, with electrodes 310 which control the liquid crystals;
a liquid crystal layer 303;
a filtering layer 305, with color filters deposited on a substrate;
an upper polarizer layer (not shown);
an upper capacitive electrode layer 601, with a matrix of capacitance measurement-electrodes 502;
protective glass 101.

The capacitive electrode layer 601 is implemented with a deposit of transparent conducting material, such as ITO or nanowires, on a dielectric surface In the embodiment shown, it is deposited on the substrate which supports the color filters. It comprises capacitive electrodes 502 distributed on the display surface according to a matrix arrangement.

According to embodiments, the capacitive electrode layer 601 is implemented near (or as a replacement for) the antistatic conducting layer 308 present in this display technology such as shown in FIG. 3. Since space between the electrodes is reduced, the electrode layer 601 also functions as an antistatic layer.

In this variant, if the electronic control of the display is not referenced to the guard potential, it is preferable to also maintain the electrodes of the control electrodes layer 307 at the guard potential during capacitance measurement sequences in order to avoid capacitive leakage between the capacitance measurement-electrodes 601 and the electrodes from this control layer 307. To that end, it generally suffices to allow these electrodes of the control layer 307 to float electrically in an open circuit. Indeed, since the coupling capacitance thereof with the guard elements (including the common potential layer 304) is much greater than the coupling capacitance thereof with the bulk ground, these electrodes of the control layer 307 polarize naturally at the guard potential to contribute to the guard elements.

FIG. 7 shows the first interface mechanism embodiment according to the invention in a variant integrated into an AMOLED type display screen. As previously explained, the mechanism shown in FIG. 7 corresponds to a schematic representation of the display shown in FIG. 4, modified according to the invention.

In the embodiment shown, the interface mechanism includes in particular the following successive elements:
a command layer 402 which comprises in particular thin-film technology (TFT) transistors and command electrodes;
a layer of organic materials 403 arranged in stack form in order to build up junctions of light-emitting diodes;
a common potential layer 404, also used as guard element;
a dielectric insulating layer 700;
an upper capacitive electrode layer 701, with a matrix of capacitance measurement-electrodes 502;
protective glass 101.

The capacitive electrode layer 701 is implemented with a deposit of transparent conducting material, such as ITO or nanowires, on a dielectric surface It comprises capacitive electrodes 502 distributed on the display surface according to a matrix arrangement.

In the embodiment presented, the capacitive electrode 701 and the common potential 404 layers are deposited on both sides of the dielectric insulating layer 700.

Embodiment of in-Cell Type Interface Mechanism:

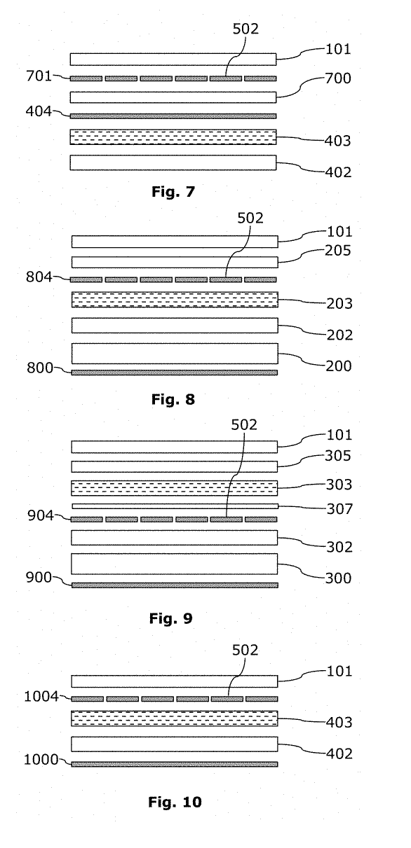

A second embodiment of the interface mechanisms according to the invention is now going to be described with reference to FIGS. 8, 9 and 10 in variants incorporated respectively in:
an active matrix LCD type display screen (FIG. 8);
an LCD type display screen with IPS technology (FIG. 9);
an AMOLED type display screen (FIG. 10).

The display screen technologies implemented in these various embodiments are described in detail in connection with FIGS. 2, 3 and 4, respectively. Also, in order to be clear and concise, they are only shown in a schematic form of superposed layers in FIGS. 8, 9 and 10.

In this embodiment, the interface mechanism according to the invention includes capacitance measurement-electrodes integrated near the common potential layer. This embodiment is therefore of the in-cell type.

As previously explained, these capacitance measurement-electrodes are excited to an alternating excitation electric potential. In order to avoid parasitic coupling, they must be protected or surrounded by polarized guard elements at a guard potential identical or substantially identical to the excitation potential, at least at measurement frequencies corresponding to the electric potential excitation frequencies.

Thus, in these embodiments, in order to avoid leakage capacitances, the electrical circuits of the display located underneath the capacitive electrodes (including in particular those from the command layer with the TFT transistors) are referenced to the guard potential.

In this way, they do not generate voltage differences at the excitation frequencies which could lead to leakage capacitances and they furthermore constitute guard elements which protect the capacitance measurement-electrodes from the influences of the remainder of the electronics.

Depending on the embodiments, it is possible to use as guard elements only display elements referenced to the guard potential.

However, in general, these circuits only partially cover the bottom of the surface of the capacitive electrodes and therefore constitute an imperfect guard with capacitive leaks.

In that way, according to the preferred embodiments, a lower guard layer is added which covers the surface of the electrodes near the lower layers of the display or underneath the display (meaning towards the side thereof opposite the viewing surface), according to an “under-cell” placement.

In these embodiments, the common potential layer is therefore structured in the form of a matrix of electrodes, for example of ITO. During capacitance measurements, the electrodes are polled sequentially as will be explained later. In that way, each electrode is connected, at a given moment, either to the input of the electronics for capacitance measurement or to the guard potential by an electronic switch. Additionally, the electrodes, whether measuring or not, are at identical guard potentials (at least at the excitation frequencies). They can therefore be used as common potential layer for the display.

In the second embodiment of the invention, the command layer with the TFT transistors and their command traces and the common potential layer with the capacitance measurement-electrodes are only separated by a few microns of insulating material made up according to the case by the liquid crystal layer or the organic material layer. In general, the surface area covered by the TFT transistors and their command traces is small compared to the total display surface but it can just the same represent several tens of percent of this total surface area of the display screen. This can pose a problem to the extent where relatively large value coupling capacitances are created between the capacitance measurement-electrodes and guard elements made up of these TFT transistors and their connecting traces. These coupling capacitances do not generate leakage capacitances because they are between elements all polarized at the same guard potential, but they constitute potentially excessive loads for the input to the detection electronics, particularly when a charge amplifier is implemented.

According to the embodiments, the capacitance measurement-electrodes (or the corresponding common potential layer) then have openings such that they do not have conducting material in the areas which are located facing TFT transistors and if possible their command traces. It is also possible to significantly reduce the coupling capacitance naturally created between each capacitance measurement-electrode and the guard elements.

The removal of conducting material from the capacitance measurement-electrodes reduces the total surface area of each electrode. This reduction reduces the capacitance measurement sensitivity in the ratio of surface areas, but the capacitive signal to noise ratio is not or only slightly impacted. In fact, the noise gain of a charge amplifier depends directly on the coupling capacitance between each capacitive electrode and the guard, and this coupling capacitance decreases with the surface area of the electrode, meaning with the reduction of the capacitive sensitivity.

FIG. 8 shows the second interface mechanism embodiment according to the invention in a variant integrated into an active matrix LCD type display screen. As previously explained, the mechanism shown in FIG. 8 corresponds to a schematic representation of the display shown in FIG. 2, modified according to the invention.

In the embodiment shown, the interface mechanism includes in particular the following successive elements:
a lower guard layer 800;
a backlighting layer 200, for example based on light-emitting diodes;
a lower polarizer layer (not shown). This polarizer layer may be omitted based on the polarization of the incident light;
a command layer 202 which comprises in particular thin-film technology (TFT) transistors and command electrodes;
a liquid crystal layer 203;
a common potential layer 804 which also supports the capacitance measurement-electrodes 502;
a filtering layer 205, with color filters deposited on a substrate;
an upper polarizer layer (not shown);
protective glass 101.

In this embodiment, the lower guard layer 800 is placed under the backlighting layer 200. The solution has the advantage of enabling an integration of the lower guard layer 800 with the display screen that is often simpler because it allows the use of a simple metal material, for example copper (e.g. metallization, conducting adhesive, etc.), for this layer. This lower guard layer 800 can additionally be protected by electrical insulation in order to avoid any oxidation over time and to avoid any short-circuit with the device in which the screen is integrated.

According to other embodiments, the lower guard layer can be placed between the command layer 202 and the backlighting layer 200. In this case, this lower guard layer must be of transparent material like for example ITO.

In these embodiments, the capacitance measurements and the refresh operations of the display can be executed simultaneously because they do not interfere and do not require a reconfiguration of the electronics. It is simply preferable to perform these operations synchronously by taking the precaution of avoiding the appearance of transients at critical or sensitive moments of one or the other of the processes of measurement and display.

FIG. 9 shows the second interface mechanism embodiment according to the invention in a variant integrated into an LCD type display screen with IPS technology. As previously explained, the mechanism shown in FIG. 9 corresponds to a schematic representation of the display shown in FIG. 3, modified according to the invention. In the embodiment shown, the interface mechanism includes in particular the following successive elements:
a lower guard layer 900;
a backlighting layer 300, for example based on light-emitting diodes;
a lower polarizer layer (not shown). This polarizer layer may be omitted based on the polarization of the incident light;
a command layer 302 which comprises in particular thin-film technology (TFT) transistors;
a common potential layer 904 which also supports the capacitance measurement-electrodes 502;
a control electrode layer 307, with electrodes 310 which control the liquid crystals;
a liquid crystal layer 303;
a filtering layer 305, with color filters deposited on a substrate;
an upper polarizer layer (not shown);
protective glass 101.

In this embodiment, the lower guard layer 900 is placed under the backlighting layer 200. The solution has the advantage of enabling an integration of the lower guard layer 900 with the display screen that is often simpler because it allows the use of a simple metal material, for example copper (e.g. metallization, conducting adhesive, etc.), for this layer. This lower guard layer 900 can additionally be protected by electrical insulation in order to avoid any oxidation over time and to avoid any short-circuit with the device in which the screen is integrated.

According to other embodiments, the lower guard layer can be placed between the command layer 302 and the backlighting layer 300. In this case, this lower guard layer must be of transparent material like for example ITO.

In this embodiment, the control electrode layer 307 with control electrodes 310 which control the liquid crystal layer 303 is placed in front of the capacitance measurement-electrodes 502 of the common potential layer 904 or towards the detection surface relative to these electrodes. In this way, even if they are at the guard potential, these control electrodes 310 can degrade the measurement of the capacitive electrodes by forming a partial screen in front of them.

In order to avoid this effect, the mechanism from the invention includes means of isolation in order to electrically disconnect and isolate the control electrodes 310 during capacitance measurement. These means of isolation are designed so as to be able to selectively isolate these control electrodes 310 by pixel or by groups of pixels.

These means of isolation can be implemented by the TFT transistors of the command layer 302, as will be explained later. In this case, it is simply necessary to take the precaution of implementing these TFT transistors so as to limit the parasitic capacitances between their terminals.

Depending on the variants, the means of isolation can include switches or additional switches.

When the control electrodes 310 for the pixels are disconnected, they become electrically floating and naturally couple with the capacitance measurement-electrodes 502. In fact, the thickness of the insulating layer separating the control electrodes 310 for the pixels from the capacitance measurement-electrodes 502 is very thin, in the range of a few microns. Thus the coupling capacitances between these control electrodes 310 and the capacitance measurement-electrodes 502 are very large. Under these conditions it can be considered that the control electrodes 310 for the pixels cause nearly no disruption to the operation and sensitivity of the capacitance measurement-electrodes 502.

Under these conditions, the capacitance measurements and the operations for refreshing the display must be done sequentially: when one capacitance measurement-electrode 502 is switched to the measurement electronics, the control electrodes 310 for the pixels covered by this capacitance measurement-electrode (which corresponds to a portion of the common potential layer 904) are switched into floating or isolated mode. This switching can be done over the entirety of the display screen, or else only a portion, or even solely over the area covered by the capaciance measurement electrode 502.

FIG. 10 shows the second interface mechanism embodiment according to the invention in a variant integrated into an AMOLED type display screen. As previously explained, the mechanism shown in FIG. 10 corresponds to a schematic representation of the display shown in FIG. 4, modified according to the invention.

In the embodiment shown, the interface mechanism includes in particular the following successive elements:
a lower guard layer 1000;
a command layer 402 which comprises in particular thin-film technology (TFT) transistors and command electrodes;
a layer of organic materials 403 arranged in stack form in order to build up junctions of light-emitting diodes;
a common potential layer 1004 which also supports the capacitance measurement-electrodes 502;
protective glass 101.

In this embodiment, the lower guard layer 1000 can be implemented with a simple metal material like for example copper (e.g. metallization, conducting adhesive, etc.). This lower guard layer 1000 can additionally be protected by electrical insulation in order to avoid any oxidation over time and to avoid any short-circuit with the device in which the screen is integrated.

In this embodiment, it is preferable to avoid refreshing display screen pixels which are connected to a portion of the common potential layer corresponding to a capacitance measurement-electrode 502 while it is measuring (meaning connected, at that time, to the input of the capacitance measurement electronics). In fact there is a risk the currents injected into the common potential layer could saturate the input stages of the detection electronics, in particular if a charge amplifier is used.

The capacitance measurements and the operations for refreshing the screen must therefore preferably be done sequentially: when one capacitance measurement-electrode 502 is switched to the measurement electronics, the pixels covered by this capacitance measurement-electrode (which corresponds to a portion of the common potential layer 1004) are not refreshed. Just the same, it is possible to perform the 2 operations simultaneously, but on different portions the screen.

Embodiment of the Electronics:

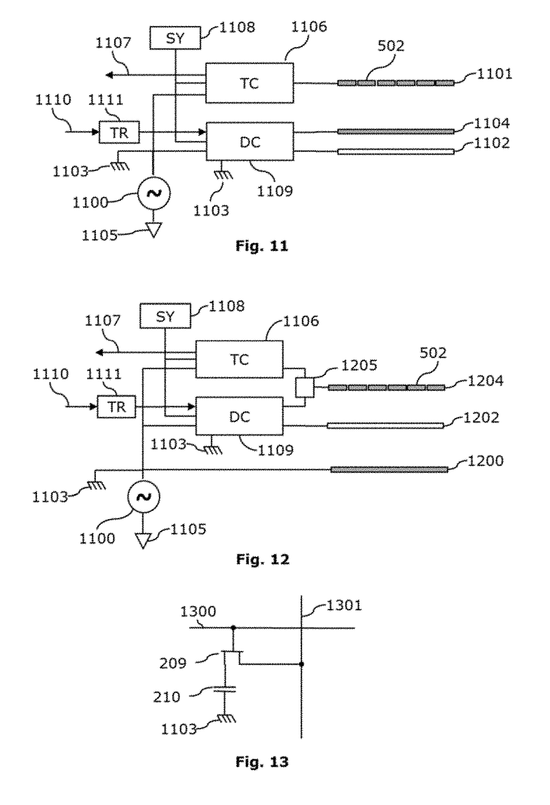

With reference to FIG. 11, an embodiment is now going to be presented for electronics for controlling the interface mechanism from the invention in the first embodiment thereof, such as described with reference to FIGS. 5, 6 and 7.

The mechanism includes display control electronics 1109, which manages the display according to the display instructions 1110.

This display control electronics 1109 in particular manages the TFT transistors of the command layer 1102 in order to drive the pixels. This command layer 1102 corresponds respectively to the command layers 202, 302 or 402 from FIG. 5, 6 or 7 depending on the display technology implemented.

The display control electronics 1109 also manages the common potential layer 1104. This common potential layer 1104 corresponds respectively to the common potential layers Vcom 204 or 304 from FIG. 5 or 6 or to the cathode from FIG. 7, depending on the display technology implemented.

The mechanism also includes capacitance measurement electronics 1106, which manages the capacitance measurement-electrodes 502 of the upper capacitive electrode layer 1101. This upper capacitive electrode layer 1101 corresponds respectively to the upper capacitive electrode layers 501, 601 or 701 from FIG. 5, 6 or 7, depending on the display technology implemented.

The capacitance measurement electronics 1106 serve to perform measurements of capacitive coupling between the electrodes 502 and the command objects 100, in such a way as to produce location and/or distance information 1107 for command objects 100 which can be used by the interface.

The mechanism also includes means of synchronization 1108 serving to drive the display control electronics 1109 and the capacitance measurement electronics 1106 consistently.

The mechanism also comprises an oscillator 1100 which generates an alternating reference voltage at at least one reference frequency. This oscillator 1100 is referenced to the bulk ground 1105 of the system. The alternating reference voltage generated in that way is used as a reference potential 1103 or as a guard potential 1103 for the capacitance measurements.

The capacitance measurement-electrodes 502 are excited to this reference potential 1103.

In the embodiment shown, the display control electronics 1109 is referenced to this reference potential 1103. In that way, at the one or more reference frequencies considered, the command layer 1102 and the common potential layer 1104 are also at this reference potential and in that way contribute to the guard elements, as previously described.

The mechanism also comprises means of signal transfer 1111 connected at the output of the display control electronics 1109, which serves to transfer the display instruction signals 1110 referenced to the bulk ground 1105 from the system to the display control electronics 1109 referenced to the reference potential 1103. The means of signal transfer 1111 can include for example differential amplifiers or optical couplers.

It should be noted that the common potential layer 1104, like the rest of the electronics, can have a nonzero potential difference (direct or alternating) relative to the reference alternating voltage insofar as this potential difference remains zero or very small at the one or more reference frequencies.

With reference to FIG. 12, an embodiment is now going to be presented for electronics for controlling the interface mechanism from the invention in the second embodiment thereof, such as described with reference to FIGS. 8, 9 and 10.

As before, the mechanism includes display control electronics 1109, which manages the display according to the display instructions 1110.

This display control electronics 1109 in particular manages the TFT transistors of the command layer 1202 in order to drive the pixels. This command layer 1202 corresponds respectively to the command layers 202, 302 or 402 from FIG. 8, 9 or 10 depending on the display technology implemented.

The display control electronics 1109 also manages the common potential layer 1204. This common potential layer 1204 corresponds respectively to the common potential layers Vcom 804 or 904 from FIG. 8 or 9 or to the cathode 1004 from FIG. 10, depending on the display technology implemented.

In this embodiment, the common potential layer 1204 also comprises capacitance measurement-electrodes 502.

The mechanism also includes capacitance measurement electronics 1106, which manages the capacitance measurement-electrodes 502 from the common potential layer 1204.

The capacitance measurement electronics 1106 serve to perform measurements of capacitive coupling between the electrodes 502 and the command objects 100, in such a way as to produce location and/or distance information 1107 for command objects 100 which can be used by the interface.

The mechanism also includes means of synchronization 1108 serving to drive the display control electronics 1109 and the capacitance measurement electronics 1106 consistently.

The mechanism also comprises an oscillator 1100 which generates an alternating reference voltage at at least one reference frequency. This oscillator 1100 is referenced to the general system ground 1105. The alternating reference voltage generated in that way is used as a reference potential 1103 or as a guard potential 1103 for the capacitance measurements.

The capacitance measurement-electrodes 502 are excited at this reference potential 1103.

The lower guard layer 1200, which corresponds respectively to the lower guard layers 800, 900 or 1000 from FIG. 8, 9 or 10 depending on the display technology implemented, is also polarized to this reference potential 1103.

In the embodiment shown, the display control electronics 1109 is referenced to this reference potential 1103. In that way, at the one or more frequencies considered, the command layer 1102 and the common potential layer 1204 are also at this reference potential and in that way contribute to the guard elements, as previously described.

The mechanism also comprises means of signal transfer 1111 connected at the output of the display control electronics 1109, which serves to transfer the display instruction signals 1110 referenced to the bulk ground 1105 from the system to the display control electronics 1109 referenced to the reference potential 1103. The means of signal transfer 1111 can include for example differential amplifiers or optical couplers.

The common potential layer 1204 with the capacitance measurement-electrodes 502 is connected to the capacitance measurement electronics 1106 and to the display control electronics 1109 by means of switching 1205, which makes it possible to operate for either display or for capacitance measurements. These means of switching 1205 are shown separately for reasons of clarity, but their operation can be simply performed by means for polling the electrodes with which to selectively connect the capacitive electrodes 205 to the input of the capacitance measurement electronics 1106.

More precisely, the means of switching 1205 serve to connect the portions or sectors of the common potential layer 1204 corresponding to some electrodes 205, either to the input of the capacitance measurement electronics 1106 in order to perform measurements or to the potential of the Vcom or cathode layer in order to drive the display of pixels.

It should be noted that the potential of the Vcom (or cathode) layer, like the rest of the electronics, can have a nonzero potential difference (direct or alternating) relative to the reference alternating voltage insofar as this potential difference remains zero or very small at the one or more reference frequencies.

With reference to FIG. 13, an example schematic drawing of control electronics is now going to be described for an LCD technology display, for the part implemented in the control layer. More specifically, the drawing from FIG. 13 corresponds to the control electronics for one pixel, such as shown in FIG. 2.

The pixels, distributed according to a matrix arrangement, are controlled by command lines 1300 distributed along a first direction and data lines 1301 distributed along a second crossed direction of the control layer.

When the TFT transistor 209 is made passing by a signal from the command line 1300, it transfers the voltage present on the command line 1301 to the command electrode 210 for the pixel. This electrode forms a capacitor referenced to the common reference potential 1103, such as shown in FIG. 13.

When the TFT transistor 209 is blocked, the charges stored in the storage capacitor formed by the command electrode 210 (and possibly supported by a storage capacitor in parallel) generate a voltage which keeps the pixel lit.

The drawing from FIG. 13 is also applicable to the control of the display screen in IPS technology, such as shown in FIG. 3.

In this case, the isolation of the command electrode 210 for the pixel, which is desirable in the second embodiment described in connection with FIG. 9 (IPS technology) during capacitance measurements, can be obtained simply with the TFT transistor 209 in blocked mode.

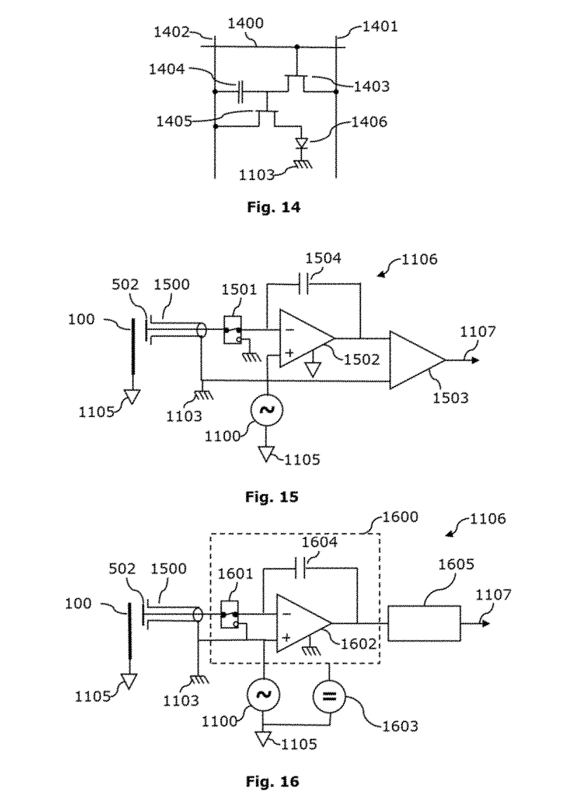

With reference to FIG. 14, an example schematic drawing of control electronics is now going to be described for an AMOLED technology display, for the part implemented in the control layer. More specifically, the drawing from FIG. 14 corresponds to the control electronics for one pixel.

The pixels, distributed according to a matrix arrangement, are controlled by command lines 1400 distributed along a first direction and data lines 1401 distributed along a second crossed direction of the control layer. VDD supply lines 1402 are also present.

The drawing comprises a first TFT transistor 1403 which enables selection of the pixel and a second TFT transistor 1405 in order to supply the light-emitting diode 1406 making up the pixel with current. This diode 1406 is referenced to the common cathode potential 1103.

A storage capacitor 1404 is also present for maintaining the light intensity of the pixel.

With reference to FIG. 15, a first sample embodiment of capacitive detection electronics 1106 is now going to be described, which is applicable to all previously described embodiments of the invention.

The electrical drawing implemented in this embodiment is based on a charge amplifier 1502 shown in the form of an operational amplifier 1502 with a feedback capacitor 1504.

It serves to measure the capacitance between a command object 100 at the bulk system ground 1105 and a capacitance measurement-electrode 502. As previously explained, the measurement of this capacitance serves to deduce, for example, the distance between the object 100 and the measurement electrode 502.

The measurement electrode 502 is connected to the input (−) of the charge amplifier 1502.

The input (+) of the charge amplifier 1502 is excited by an oscillator 1100 which delivers an alternating reference voltage 1103, also called guard potential 1103. In that way the measurement electrode 502 is polarized substantially to this same reference voltage 1103.

The charge amplifier output is connected to a differential amplifier 1503 which serves to obtain a voltage at the output representative of the capacitances at the input of the charge amplifier 1502, and in that way produce information on the location and/or distances 1107 of command objects 100 usable by the interface.

The mechanism also includes guard elements 1500 intended to protect the measurement electrodes 502 and the elements for connection between the electrodes 502 and the electronics. These guard elements 1500 are polarized at the guard potential 1103 generated by the oscillator 1100, which is in that way used as an excitation potential in order to generate an active guard approximately at the same potential as the measurement electrodes 502.

Depending on the embodiments, these guard elements 1500 can in particular comprise the common potential layers and/or the lower guard layers.

The mechanism also includes means for polling or switches 1501 which serve to select the electrodes 502. These switches 1501 are arranged such that an electrode 502 is either connected to the charge amplifier and measuring, or connected to the guard potential 1103 in order to contribute to the guard elements 1500.

The switches 1501 serve to sequentially measure over a plurality of measurement electrodes 502 with a single charge amplifier 1502.

Of course, the capacitive detection electronics 1106 may include several charge amplifiers 1502 operating in parallel and serving to simultaneously measure with a plurality of electrodes 502. The capacitive detection electronics 1106 may in particular comprise:
as many charge amplifiers 1502 as measurement electrodes 502. This configuration makes it possible to perform measurements in parallel, simultaneously, on all of the measurement electrodes 502. In this case, it is possible not to implement switches 1501;
a plurality of charge amplifiers 1502 arranged so that each can be connected, via a plurality of switches 1501, to a group of measurement electrodes 502. This configuration makes it possible to perform measurements in parallel in groups of measurement electrodes 502, where the electrodes in a group are queried sequentially;
a single charge amplifier 1502 arranged so that it can be connected via switches 1501 to all of the measurement electrodes 502.

According to one advantageous aspect of the embodiment of capacitive detection electronics 1106 described in relation to FIG. 15, all the measurement electrodes 502, whether they are measuring (i.e., connected to a charge amplifier) or non-measuring (and therefore connected to the guard potential 1103), are at a single guard potential 1103. Indeed, the one or more charge amplifiers 1502 and the one or more switches 1501 implemented are all connected to the same guard potential 1103 common to all of the capacitive detection electronics 1106. Furthermore, because of the principle of detection by charge amplifier used, the potential of the measurement electrodes 502 does not vary with the measured capacitances. Any parasitic coupling and any cross-talk between the measurement electrodes 502, irrespective of whether they are measuring, and between the measurement electrodes 502 and the guard elements 1500 can be avoided. A plurality of charge amplifiers 1502 and switches 1501 can also be implemented by implementing an active guard that is very effective at a single guard potential 1103.

Furthermore, in particular in the second, in-cell embodiment of the invention described with reference to FIGS. 8, 9 and 10 with display control electronics 1109 referenced to the guard potential, the switches 1501 may also be used in order to configure the non-measuring electrodes 502 as elements of the common potential layer suited for control of the display pixels.

In this embodiment of capacitive detection electronics, the capacitive detection electronics 1106 with the charge amplifier 1502 and the differential amplifier 1503 are globally referenced to the bulk ground 1105.

Just the same, this embodiment has the disadvantage of allowing the presence of leakage capacitances between the electrodes 502 and/or the input of the charge amplifier 1502, and elements at the bulk ground potential 1105.

With reference to FIG. 16, a second sample embodiment of capacitive detection electronics 1106 is now going to be described, which is applicable to all previously described embodiments of the invention.

It also serves to measure the capacitance between a command object 100 at the bulk system ground 1105 and a capacitance measurement-electrode 502. As previously explained, the measurement of this capacitance serves to deduce, for example, the distance between the object 100 and the measurement electrode 502.

In this embodiment, the electronics include a portion called “floating” 1600 globally referenced to an alternating reference potential 1103 (or guard potential) generated by an oscillator 1100. Thus, leakage capacitances cannot appear, because all the elements, including the electrodes 502 and the sensitive part of the detection electronics, are at the same guard potential. In that way, high sensitivities can be obtained and command objects 100 can be detected at distances of several centimeters.

This type of detection electronics, referred to as “floating reference” or “floating bridge”, is in particular described in detail in the Rozière patent FR 2,756,048. Also, for reasons of conciseness, only the essential features are reviewed here.

As before, the electrical drawing implemented in this embodiment is based on a charge amplifier 1602 shown in the form of an operational amplifier 1602 with a feedback capacitor 1604.

The charge amplifier 1602, like the whole sensitive portion of the detection electronics, is referenced to the guard potential 1103 and therefore makes up part of the floating portion 1600 of the electronics.

This floating portion 1600 can of course include other means of processing and conditioning the signal, including digital or microprocessor-based, also referenced to the guard potential 1103. These means of processing and conditioning serve for example to calculate distance and position information from capacitance measurements.

The electric supply of the floating portion 1600 is provided by floating means of supply transfer 1603, comprising for example DC/DC converters.

The floating electronics 1600 is connected at the output to the device electronics referenced to the bulk ground 1105 by connection elements 1605 compatible with the difference in reference potentials. These connection elements 1605 can include for example differential amplifiers or optical couplers. In that way, at the output of these connection elements 1605 location and/or distance information 1107 for control objects 100 is obtained that is usable by the interface.

In the embodiment shown, the measurement electrode 502 is connected to the input (−) of the charge amplifier 1602.

The input (+) of the charge amplifier 1602 is excited by an oscillator 1100 which delivers an alternating reference voltage 1103, or guard potential 1103. In that way the measurement electrode 502 is polarized substantially to this same reference voltage 1103.

The mechanism also includes guard elements 1500 intended to protect the measurement electrodes 502 and the elements for connection between the electrodes 502 and the electronics. These guard elements 1500 are polarized to the guard potential 1103 generated by the oscillator 1100, which is therefore also the reference potential for the floating electronics 1600.

Depending on the embodiments, these guard elements 1500 can in particular comprise the common potential layers and/or the lower guard layers.

The mechanism also includes means for polling or switches 1601 which serve to select the electrodes 502. Thus. These switches 1601 are arranged such that an electrode 502 is either connected to the charge amplifier 1602 and measuring, or connected to the guard potential 1103 in order to contribute to the guard elements 1500.

The switches 1601 make it possible to sequentially measure over a plurality of measurement electrodes 502 with a single charge amplifier 1602.

Of course, the capacitive detection electronics 1106 may include several charge amplifiers 1602 operating in parallel and making it possible to measure simultaneously on a plurality of electrodes 502.

The capacitive detection electronics 1106 may in particular comprise:
as many charge amplifiers 1602 as measurement electrodes 502. This configuration makes it possible to perform measurements in parallel, simultaneously, on all of the measurement electrodes 502. In this case, it is possible to not implement switches 1601;
a plurality of charge amplifiers 1602 arranged so each can be connected to a group of measurement electrodes 502 via a plurality of switches 1601. This configuration makes it possible to measure groups of measurement electrodes 502 in parallel, where the electrodes in a group are queried sequentially;
a single charge amplifier 1602 arranged so that it can be connected via switches 1601 to all of the measurement electrodes 502.

As before, in the embodiment of capacitive detection electronics 1106 described in relation to FIG. 16, all of the measurement electrodes 502, whether they are measuring (i.e., connected to a charge amplifier) or non-measuring (and therefore connected to the guard potential 1103), are at a single guard potential 1103. Indeed, the charge amplifier(s) 1602 and the switch or switches 1601 implemented are all connected to the same guard potential 1103 common to all of the capacitive detection electronics 1106. Furthermore, because of the detection principle by charge amplifier implemented, the potential of the measurement electrodes 502 does not vary with the measured capacitances. Any parasitic coupling and any cross-talk between the measurement electrodes 502, irrespective of whether they are measuring, and between the measurement electrodes 502 and the guard elements 1500 can be avoided.

It is also possible to implement a plurality of charge amplifiers 1602 and switches 1601 by implementing a very effective active guard at a single guard potential 1103.

Preferably, the switches 1601 are also referenced to the reference potential of the floating electronics 1600.

It is also possible to implement switches 1601 referenced to the bulk ground 1105. This solution has the drawback of generating parasitic capacitances between the charge amplifier input and the bulk ground 1105. However, in particular in the case where the switches 1601 are made with transistors of the FET, MOS or MOSFET type (or TFT if they are implemented in the display), these parasitic capacitances that appear between the gate and the drain or the source of the transistor can be kept small, of approximately several femtofarads.

Furthermore, in particular in the second, in-cell embodiment of the invention described with reference to FIGS. 8, 9 and 10 with display control electronics 1109 referenced to the guard potential, the switches 1601 may also be used in order to configure the non-measuring electrodes 502 as elements of the common potential layer suited for control of the display pixels.

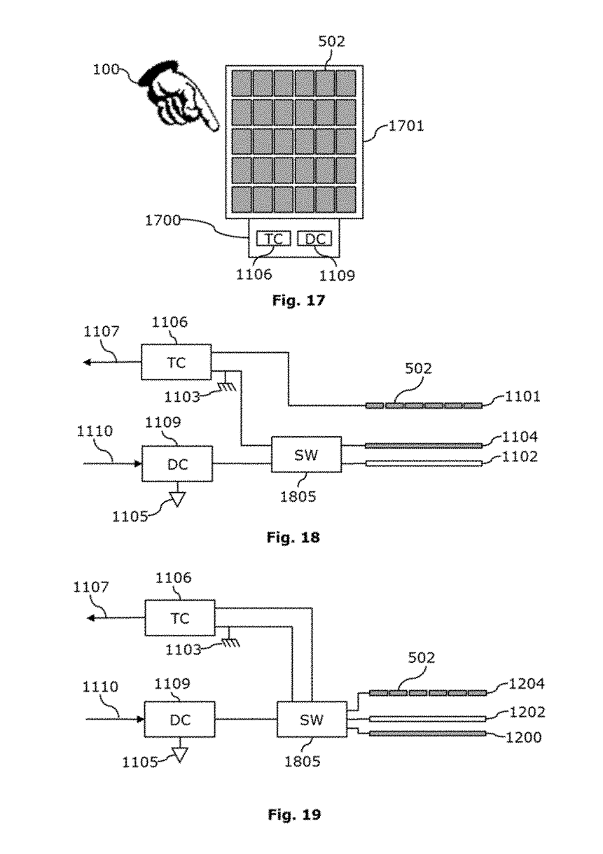

In practice, an interface mechanism according to the invention is frequently arranged according to the arrangement illustrated in FIG. 17. This type of arrangement is for example encountered for interface mechanisms intended to be integrated into devices of the smartphone or tablet type, or in a display system (screen).

According to this arrangement, the mechanism comprises a display zone 1701 with superposed display pixels and capacitance measurement electrodes 502.

It also comprises one or more integrated circuits that implement the display control electronics 1109 and the capacitance measurement electronics 1106, for example in the form of two separate integrated circuits as illustrated in FIG. 17, or a single integrated circuit grouping together both functions. This or these integrated circuit(s) are united near the display zone 1701, outside the latter. They may for example be united on a flexible printed circuit 1700 as illustrated FIG. 17.

Under these conditions, what matters for the quality of the capacitance measurement is that the parts of the display that are near the capacitance measurement electrodes 502 be referenced to the guard potential 1103 during the capacitance measurement phases. These parts correspond for the most part to the display zone 1701. If the integrated circuit that implements the display control electronics 1109 is far enough away from the capacitance measurement electrodes 502, it may not in itself generate significant parasitic capacitive couplings. This is the case for the configuration shown in FIG. 17.

In this case, it is possible to implement display control electronics 1109 with an integrated circuit referenced to the bulk ground 1105 of the system. This solution in particular has the advantage, compared to the embodiments of control electronics described in FIGS. 11 and 12, of allowing simpler interfacing of the display instruction signals 1110 referenced to the bulk ground 1105 with the display control electronics 1109.

On-Cell Implementation with Switched Electronics:

With reference to FIG. 18, an embodiment is now going to be presented for electronics for controlling the interface mechanism from the invention in the first embodiment thereof, such as described with reference to FIGS. 5, 6 and 7 (of the on-cell type), in which display control electronics 1109 are implemented with an integrated circuit referenced to the bulk ground 1105 of the system.

This embodiment corresponds to the first control electronics configuration as described relative to FIGS. 5, 6 and 7.

The mechanism includes capacitance measurement electronics 1106, which manages the capacitance measurement-electrodes 502 of the upper capacitive electrode layer 1101. This upper capacitive electrode layer 1101 corresponds respectively to the upper capacitive electrode layers 501, 601 or 701 from FIG. 5, 6 or 7, depending on the display technology implemented.

These capacitance measurement electronics 1106 may be implemented in particular by using the embodiment from FIG. 15, with an active guard at the guard potential 1103, or that of FIG. 16, with electronics globally referenced to the guard potential 1103.

The mechanism includes display control electronics 1109, which manages the display according to the display instructions 1110. These display control electronics 1109 are at least partially referenced to the bulk ground 1105 of the system.

The display control electronics 1109 in particular manages the TFT transistors of the command layer 1102 in order to drive the pixels. This command layer 1102 corresponds respectively to the command layers 202, 302 or 402 from FIG. 5, 6 or 7 depending on the display technology implemented.

The mechanism also comprises a switching module 1805 that is inserted between the display control electronics 1109 and the elements of the control layer 1102. The function of this switching module 1805 is in particular to configure the elements of the command layer 1102, so as to allow either capacitance measurements, or refresh operations of the display.

This switching module 1805 also manages the common potential layer 1104. This common potential layer 1104 corresponds respectively to the common potential layers Vcom 204 or 304 from FIG. 5 or 6 or to the cathode 404 from FIG. 7, depending on the display technology implemented. As explained in relation with FIGS. 5, 6 and 7, the switching module 1805 in particular makes it possible to switch the common potential layer 1104 to the guard potential 1103 during capacitance measurements.

In the embodiment shown in FIG. 18, this guard potential 1103 is sent to the switching module 1805 by the capacitance measurement electronics 1106.

The switching module 1805 therefore serves to interface the display control electronics 1109 (for example made in the form of an integrated circuit as illustrated in FIG. 17) with elements of the display zone 1701, which in particular comprises the command layer 1102, the common potential layer 1104, and the upper capacitive electrode layer 1101. In this embodiment, the capacitance measurement electronics 1106 can be directly connected to the upper capacitive electrode layer 1101.

The switching module 1805 for the most part designates a functional set of switches or multiplexers that may, without limitation, be:
grouped together in one or several components;
distributed or broken down in different locations on or around the display zone 1701, and/or in other locations such as on the flexible printed circuit 1700 of FIG. 17;
included in an integrated circuit implementing the display control electronics 1109 and/or the capacitance measurement electronics 1106;
implemented in the form of integrated component(s);
implemented in the form of switches made with TFT transistors on the border of the display zone 1701.

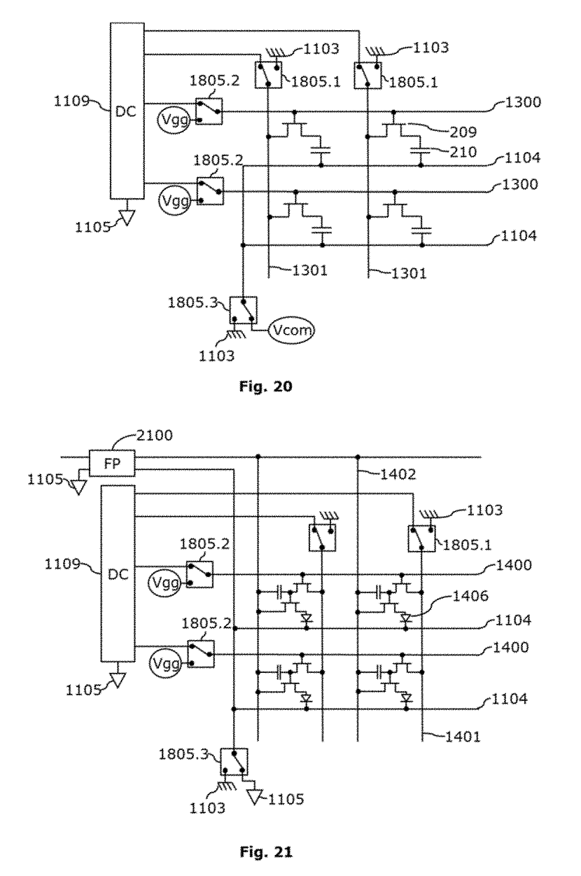

In reference to FIG. 20, we will now describe one embodiment of electronics for controlling the interface mechanism of the invention according to the embodiment of FIG. 18, to control LCD display screens (of the IPS, FFS or other technology type). This embodiment therefore makes it possible to control an interface mechanism according to the invention in its first embodiment (of the on-cell type), as in particular described relative to FIGS. 5 (active matrix LCD-type display screen) and 6 (IPS technology LCD-type display screen).

FIG. 20 illustrates a display portion with the electronics of the command layer 1102 for controlling four LCD pixels. These control electronics are described in detail in relation to FIG. 13. The command electrodes 201 of the pixels are controlled by TFT transistors 209. As explained in relation with FIG. 13, these TFT transistors 209 are connected to command lines 1300 at their gate and data lines 1301 at their source or their drain. The command lines 1300 and the data lines 1301 are located in the command layer 1102. The command electrodes 201 of the pixels form capacitors with the common potential layer 1104, shown schematically in FIG. 20 by lines 1104.

The switching module 1805 comprises:
data switches 1805.1 that connect the data lines 1301, either to the display control electronics 1109 (referenced to the bulk ground 1105), or to a direct gate voltage source Vgg referenced to the guard potential 1103;
command switches 1805.2 that connect the command lines 1300 either to the display control electronics 1109, or to the guard potential 1103;
reference switches 1805.3 that connect the common potential layer 1104 either to the common potential Vcom of the display screen (referenced to the bulk ground 1105), or to the guard potential 1103.

In the embodiment shown, the switches of the switching module 1805 are made with TFT transistors on the command layer 1102 on the border of the display zone 1701.

The reference switches 1805.3, the command switches 1805.2 and the data switches 1805.1 are preferably referenced to the guard potential 1103, or in other words driven by a signal referenced to the guard potential 1103. Thus, in the case where these switches comprise FET or TFT transistors, the signal used to control the gate of these transistors is referenced to the guard potential 1103.

They may also be referenced to the bulk ground 1105 (or driven by a signal referenced to the bulk ground 1105), which generates additional parasitic capacitances, but which in general are acceptable.

As previously explained, the switches of the switching module 1805 make it possible to configure the system either to take capacitance measurements, or to perform refresh operations of the display.

The configuration illustrated in FIG. 20 corresponds to a configuration for refreshing the display and controlling the pixels. In this configuration, the entire display screen is referenced to the bulk ground 1105 and works traditionally:
the reference switches 1805.3 are arranged so as to connect the common potential layer 1104 to the common potential Vcom of the display screen (referenced to the bulk ground 1105);
the command switches 1805.2 are arranged so as to connect the command lines 1300 to the display control electronics 1109 to control the addressing of the pixels;
the data switches 1805.1 are arranged so as to connect the data lines 1301 to the display control electronics 1109 to control the transmission of data to the pixels.

The configuration for taking capacitance measurements is done by changing the position of the switches of the switching module 1805. More specifically, in this configuration:
the reference switches 1805.3 are arranged so as to connect the common potential layer 1104 to the guard potential 1103. Thus, the common potential layer 1104 becomes a guard element 1500;
the command switches 1805.2 are arranged so as to connect the command line 1300 to the direct gate voltage source Vgg referenced to the guard potential 1103. The voltage of this gate voltage source Vgg is chosen so as to keep the TFT transistors 209 of the pixels in the blocked mode. In general, it is negative;
the data switches 1805.1 are arranged so as to connect the data lines 1301 to the guard potential 1103.

In this configuration, the data lines 1301, the command lines 1300, and more generally the elements of the command layer 1102 are referenced or connected to the guard potential and thus contribute to the guard elements 1500. They are therefore no longer able to generate parasitic capacitances with the capacitance measurement electrodes 502 of the upper capacitive electrode layer 1101.

During this capacitance measuring phase, the TFT transistor 209 of the pixel is blocked. The pixel is kept lit by the charge stored in the storage capacitor, as explained relative to FIG. 13. The command electrode 210 of the pixel is electrically uncoupled (floating). Since it is surrounded by elements at the guard potential 1103, it tends to follow this guard potential 1103 and therefore does not generate parasitic coupling with the measurement electrodes 502.

We will now describe a method for controlling the interface mechanism in this embodiment. This method comprises the following steps, repeated iteratively:
switching of the reference 1805.3, command 1805.2 and data 1805.1 switches in the described configuration to refresh the image and control the pixels;
updating the information of the pixels with the display control electronics 1109;
switching the reference 1805.3, command 1805.2 and data 1805.1 switches into the described configuration to perform capacitance measurements;
acquiring capacitance measurements on the electrodes 502 with the capacitance measurement electronics 1106.

With reference to FIG. 21, an embodiment is now going to be described for electronics for controlling the interface mechanism from the invention according to the embodiment of FIG. 18, to control AMOLED display screens.

This embodiment therefore makes it possible to control an interface mechanism according to the invention in its first embodiment (of the on-cell type), as in particular described relative to FIG. 7.

FIG. 21 illustrates a display portion with the electronics of the command layer 1102 for controlling four AMOLED pixels. These control electronics are described in detail in relation to FIG. 14. The light-emitting diodes 1406 of the pixels are controlled by TFT transistors. As explained in relation with FIG. 14, these TFT transistors are connected to command lines 1400, data lines 1401 and power lines 1402. The command lines 1400, the data lines 1401 and the power lines 1402 are located in the command layer 1102. The light-emitting diodes 1406 of the pixels are connected to the common potential layer 1104, which makes up a common cathode, and which is shown schematically in FIG. 21 by lines 1104.

The configuration of the switches of the switching module 1805 and their operation are substantially identical to that of the embodiment of FIG. 20. Thus, only the differences are described in detail, with the understanding that with the exception of these differences, what was described relative to the embodiment of FIG. 20 is also applicable to this embodiment.

The configuration illustrated in FIG. 21 corresponds to a configuration for refreshing the display and controlling the pixels.

The data switches 1805.1 are arranged to connect the data lines 1401 either to the display control electronics 1109 during the display control phases, or to a direct gate voltage source Vgg referenced at the guard potential 1103 during the capacitance measurement phases. The voltage of this gate voltage source Vgg is chosen so as to keep the TFT transistors of the pixels to which it is connected in blocked mode.

The command switches 1805.2 are arranged to connect the command lines 1400 either to the display control electronics 1109 during the display control phases, or to the guard potential 1103 during the capacitance measurement phases.

The reference switches 1805.3 are arranged to connect the common potential layer 1104 either to the cathode potential of the display screen (which references or corresponds to the bulk ground 1105) during the display control phases, or to the guard potential 1103 during the capacitance measurement phases.

As explained in relation with FIG. 14, the light-emitting diodes 1406 of the pixels must remain powered between the refresh phases of their command to remain lit. Ideally, they also need to be kept lit during the passive measurement phases to avoid flickering.

To that end, the mechanism according to the invention comprises a power source 2100 for the OLED that is electrically floating or non-referenced. In the embodiment shown, this power source 2100 includes a power source referenced to the bulk ground 1105 and power transfer means, for example with a DC/DC converter.

This power source 2100 may of course be integrated into other components, such as the display control electronics 1109 or the capacitance measurement electronics 1106.

The output of the power source 2100 is connected to the power lines 1402. The floating reference thereof is connected to the common potential layer 1104. Thus, depending on the position of the reference switches 1805.3, it is referenced to the cathode potential corresponding to the bulk ground potential 1105 during the display control phases, or to the guard potential 1103 during the capacitance measurement phases. In both cases, the voltage across the terminals thereof is substantially identical.

Thus, it is possible to keep the light-emitting diodes 1406 of the pixels lit during the capacitance measurement phases, without being disrupted by the change in electric reference of the common potential layer 1104.

In-Cell Implementation with Switched Electronics:

With reference to FIG. 19, an embodiment is now going to be presented for electronics for controlling the interface mechanism from the invention in the second embodiment thereof, such as described with reference to FIGS. 8, 9 and 10 (of the in-cell type), in which display control electronics 1109 are implemented with an integrated circuit referenced to the bulk ground 1105 of the system.

The mechanism includes capacitance measurement electronics 1106, which manages the capacitance measurement-electrodes 502 integrated at the common potential layer 1204. This common potential layer 1204 corresponds respectively to the common potential layers Vcom 804 or 904 from FIG. 8 or 9 or to the cathode 1004 from FIG. 10, depending on the display technology used.

These capacitance measurement electronics 1106 may be implemented in particular by using the embodiment from FIG. 15, with an active guard at the guard potential 1103, or that of FIG. 16, with electronics globally referenced to the guard potential 1103.

The mechanism includes display control electronics 1109, which manages the display according to the display instructions 1110. These display control electronics 1109 are at least partially referenced to the bulk ground 1105 of the system.

The display control electronics 1109 in particular manages the TFT transistors of the command layer 1202 in order to drive the pixels. This command layer 1202 corresponds respectively to the command layers 202, 302 or 402 from FIG. 8, 9 or 10 depending on the display technology implemented.

The mechanism also includes a switching module 1805 that is inserted between the display control electronics 1109 and the capacitance measurement electronics 1106 on the one hand, and the command layer 1202, the common potential layer 1204 and the lower guard layer 1200 on the other hand. The lower guard layer 1200 corresponds respectively to the lower guard layers 800, 900 or 1000 from FIG. 8, 9 or 10 depending on the display technology implemented.

The switching module 1805 in particular serves to configure the elements of the command layer 1202, so as to allow either capacitance measurements, or display refresh operations.

This switching module 1805 also manages the common potential layer 1204 with the capacitive electrodes 502. It in particular makes it possible to connect the measurement electrodes 502 to the capacitance measurement electronics 1106 for the measurements, and to switch the common potential layer 1204 to the potential Vcom or cathode to drive the screen pixels.

The switching module 1805 also makes it possible to switch the lower guard layer 1200 either to the guard potential 1103 for the capacitance measurements, or to another potential such as the bulk ground potential 1105 for display refresh operations. The lower guard layer may also be kept electrically floating, disconnected, during the display refresh operations.

According to a variant, it is possible to keep the lower guard layer 1200 at the guard potential 1103 even during the refresh operations of the display to limit the number of switches, but this solution may create additional electrical disruptions.

As in the embodiment shown with reference to FIG. 18, the function of the switching module 1805 is therefore to interface the display control electronics 1109 (for example implemented in the form of an integrated circuit as shown in FIG. 17) with elements of the display zone 1701, which in particular comprises the command layer 1202, the common potential layer 1204 with the capacitive electrodes 502, and the lower guard layer 1200.

The switching module 1805 for the most part designates a functional assembly of switches or multiplexers that may, without limitation, be:
grouped together in one or several components;
distributed or broken down in different locations on or around the display zone 1701, and/or in other locations such as on the flexible printed circuit 1700 of FIG. 17;
included in an integrated circuit implementing the display control electronics 1109 and/or the capacitance measurement electronics 1106;
implemented in the form of integrated component(s);
implemented in the form of switches made with TFT transistors on the border of the display zone 1701.

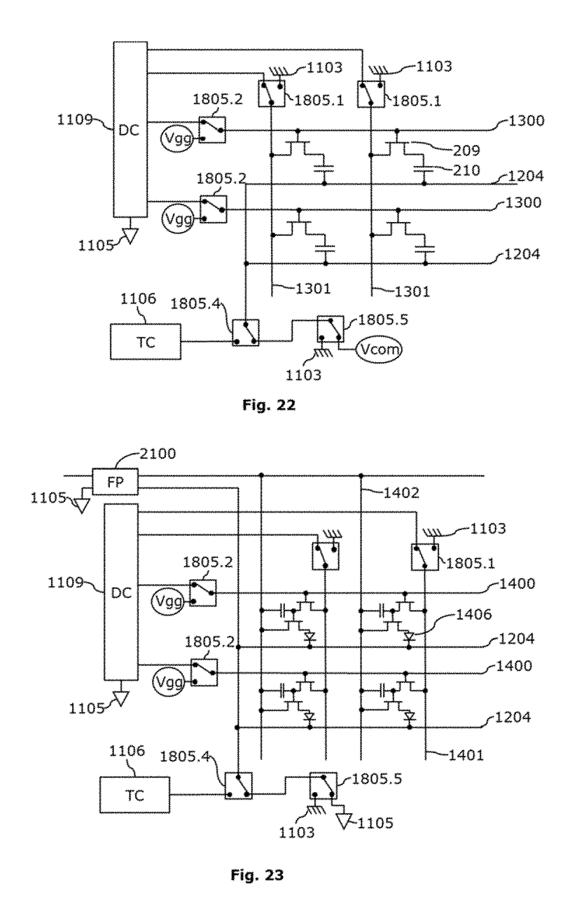

In reference to FIG. 22, an embodiment of electronics are now going to be described for controlling the interface mechanism of the invention according to the embodiment of FIG. 19, to control LCD display screens (IPS, FFS or other technology type).

With this embodiment it is therefore possible to control an interface mechanism according to the invention in its second embodiment (in-cell type), as in particular described in connection with FIGS. 8 (active matrix LCD-type display screen) and 9 (IPS technology LCD-type display screen).

FIG. 22 illustrates a display portion with the electronics of the command layer 1202 for controlling four LCD pixels. These command electronics are described in detail in relation to FIG. 13. The command electrodes 201 of the pixels are controlled by TFT transistors 209. As explained in relation with FIG. 13, these TFT transistors 209 are connected to command lines 1300 at their gate and to data lines 1301 at their source or their drain. The command lines 1300 and the data lines 1301 are located in the command layer 1204. The command electrodes 201 of the pixels form capacitors with the common potential layer 1204, schematically shown in FIG. 20 by lines 1204.

The switching module 1805 comprises data switches 1805.1 and command switches 1805.2, the configuration and operation of which are substantially identical to that of the embodiment of FIG. 20. Thus, only the differences are described in detail, with the understanding that, with the exception of these differences, what has been described relative to the embodiment of FIG. 20 is also applicable to this embodiment.

The configuration illustrated in FIG. 22 corresponds to a configuration for refreshing the display and controlling the pixels.

The data switches 1805.1 are arranged to connect the data lines 1301 either to the display control electronics 1109 during the display control phases, or to a direct gate voltage source Vgg referenced at the guard potential 1103 during the capacitance measurement phases. The voltage of this gate voltage source Vgg is chosen so as to keep the TFT transistors 209 of the pixels in blocked mode.

The command switches 1805.2 are arranged to connect the command lines 1300 either to the display control electronics 1109 during the display control phases, or to the guard potential 1103 during the capacitance measurement phases.

In this configuration, the capacitance measurement electrodes 502 are integrated into the common potential layer 1204, in the form of distinct conducting zones.

The switching module 1805 further comprises electrode switches making it possible to connect the conducting zones individually, either to the capacitance measurement electronics 1106 during the capacitance measurement phases, or to the common potential Vcom of the display screen (referenced to the bulk ground 1105) during the display control phases.

According to one preferred embodiment, an electrode switch comprises:
a first electrode switch 1805.4 that makes it possible to connect a measurement electrode 502 either to the capacitance measurement electronics 1106 during the capacitance measurement phases, or to a second electrode switch 1805.5 during the display control phases;
a second electrode switch 1805.5 that makes it possible to connect the output of the first electrode switch 1805.4 either to the guard potential 1103 during the capacitance measurement phases, or to the common potential Vcom of the display screen during the display control phases.

This configuration is illustrated in FIG. 22 for a measurement electrode 502 that covers at least the four pixels shown.

The first electrode switch 1805.4 is referenced to the guard potential 1103. The second electrode switch 1805.5 is preferably referenced to the guard potential 1103, but it may also be referenced to the bulk ground 1105. The electrode switches can be made with TFT transistors on the border of the display zone 1701, or by any other means like for the other switches of the switching module 1805.

With this configuration, the appearance of parasitic coupling capacitances between the input of the capacitance measurement electronics 1106 and the bulk ground 1105 can be avoided. Indeed, all of the voltages present at the first electrode switch 1805.4 are referenced to the guard potential 1103, and the only coupling capacitance that may appear at the second electrode switch 1805.5 is between the guard potential 1103 and the bulk ground 1105. Because of the effect of the guard, it therefore cannot affect the measurement.

The first electrode switch 1805.4 may also be used as a multiplexer during the capacitance measurement phases to connect a measurement electrode 502 either to the capacitance measurement electronics 1106, or to the guard potential 1103 via the second electrode switch 1805.5. In this case, several measurement electrodes 502 can be connected via their first electrode switch 1805.4 to a single input of the capacitance measurement electronics 1106. Of course, this input to the capacitance measurement electronics 1106 may also comprise internal polling means 1501, 1601 as described in FIGS. 15 and 16.

With reference to FIG. 23, an embodiment is now going to be described for electronics for controlling the interface mechanism from the invention according to the embodiment of FIG. 19, to control AMOLED display screens.

This embodiment therefore makes it possible to control an interface mechanism according to the invention in its second embodiment (in-cell type), as in particular described relative to FIG. 10.

FIG. 23 illustrates a display portion with the electronics of the command layer 1102 for controlling four AMOLED pixels. These control electronics are described in detail in relation to FIG. 14. The light-emitting diodes 1406 of the pixels are controlled by TFT transistors. As explained in relation with FIG. 14, these TFT transistors are connected to command lines 1400, data lines 1401 and power lines 1402. The command lines 1400, the data lines 1401 and the power lines 1402 are located in the command layer 1102. The light-emitting diodes 1406 of the pixels are connected to the common potential layer 1204, which makes up a common cathode, and which is shown schematically in FIG. 21 by lines 1204.

The switching module 1805 comprises data switches 1805.1 and command switches 1805.2, the configuration and operation of which are substantially identical to that of the embodiment of FIG. 21 (or FIG. 20). Thus, only the differences are described in detail, with the understanding that with the exception of these differences, what has been described relative to the embodiment of FIG. 21 is also applicable to this embodiment.

The configuration illustrated in FIG. 23 corresponds to a configuration for refreshing the display and controlling the pixels.

The data switches 1805.1 are arranged to connect the data lines 1401 either to the display control electronics 1109 during the display control phases, or to a direct gate voltage source Vgg referenced at the guard potential 1103 during the capacitance measurement phases. The voltage of this gate voltage source Vgg is chosen so as to keep the TFT transistors of the pixels to which it is connected in blocked mode.

The command switches 1805.2 are arranged to connect the command lines 1400 either to the display control electronics 1109 during the display control phases, or to the guard potential 1103 during the capacitance measurement phases.

The mechanism further comprises a power source for the OLED 2100, electrically floating or non-referenced, the configuration and operation of which are substantially identical to that of the embodiment of FIG. 21. Thus, only the differences are described in detail, with the understanding that with the exception of these differences, what has been described relative to the embodiment of FIG. 21 is also applicable to this embodiment.

This OLED 2100 power source makes it possible to keep the light-emitting diodes 1406 of the pixels lit during the capacitance measurement phases, without being disrupted by the change in electric reference of the common potential layer 1204. It includes a power source referenced to the bulk ground 1105 and power transfer means, for example a DC/DC converter. It is connected at the output to the power lines 1402, and its floating reference is connected to the common potential layer 1204.

The capacitance measurement electrodes 502 are integrated into the common potential layer 1204, in the form of distinct conducting zones.

The switching module 1805 further comprises electrode switches whose configuration and operation are substantially identical to that of the embodiment of FIG. 22. Thus, only the differences are described in detail, with the understanding that with the exception of these differences, what has been described relative to the embodiment of FIG. 22 is also applicable to this embodiment.

With these electrode switches, conducting zones of the common potential layer 1204 can individually be connected either to the capacitance measurement electronics 1106 during the capacitance measurement phases, or to the cathode potential shown by the bulk ground 1105 during the display control phases.

According to one preferred embodiment, one electrode switch comprises:
a first electrode switch 1805.4 that makes it possible to connect a measurement electrode 502 either to the capacitance measurement electronics 1106 during the capacitance measurement phases, or to a second electrode switch 1805.5 during the display control phases;
a second electrode switch 1805.5 that makes it possible to connect the output of the first electrode switch 1805.4 either to the guard potential 1103 during the capacitance measurement phases, or to the cathode potential represented by the bulk ground 1105 during the display control phases.

With this configuration, the appearance of parasitic coupling capacitances between the input of the capacitance measurement electronics 1106 and the bulk ground 1105 can be avoided.

As before, the first electrode switch 1805.4 may also be used as a multiplexer during the capacitance measurement phases to connect a measurement electrode 502 either to the capacitance measurement electronics 1106, or to the guard potential 1103.

According to a variant applicable to the embodiments of FIGS. 22 (in-cell configuration with an LCD screen) and 23 (in-cell configuration with an OLED screen), the electric switches are made in the form of a simple switch that makes it possible to connect an input of the capacitance measurement electronics 1106:
either to an electrode 502 for the capacitance measurements;
or to the common potential Vcom of the display screen (for the LCD screen) or the bulk ground 1105 (for the OLED screens) for display control operations.

This configuration nevertheless has the drawback of generating a large parasitic coupling capacitance at the electrode switch between the input of the capacitance measurement electronics 1106 and the bulk ground 1105, even during the capacitance measurements.

According to a variant applicable to the embodiments of FIGS. 21 (on-cell configuration with an OLED-type screen) and 23 (in-cell configuration with an OLED-type screen), the mechanism comprises a power source for the OLEDs that is not floating, but continuously referenced to the bulk ground 1105 of the system. This power source for the OLEDs may for example correspond to the source typically present in the display control electronics. In this case, the mechanism also comprises an additional source switch arranged to connect the power lines 1402 either to the power source during the display control phases, or to the guard potential 1103 during the capacitance measurement phases. This variant nevertheless has the drawback that the pixel diodes are necessarily extinguished during the capacitance measurement phases.

According to a variant to the embodiments of FIGS. 20 (on-cell configuration with LCD-type screen), 21 (on-cell configuration with an OLED-type screen), 22 (in-cell configuration with an LCD-type screen) and 23 (in-cell configuration within OLED-type screen), the command switches 1805.2 are arranged so as to connect the command lines 1300 (for LCD-type screens) or 1400 (for OLED-type screens) to the display control electronics 1109 during the display control phases, or to keep them electrically floating (in an open circuit) during the capacitance measurement phases.

In this variant, the command switches 1805.2 are therefore in the open position during the capacitance measurement phases. The command lines 1300 or 1400 are then electrically floating. The parasitic capacitance present between the gate and the source of the TFT transistors that command the pixels serve to keep them in blocked mode for a sufficient duration to cover the capacitance measuring phase.

According to another variant applicable to the embodiments of FIGS. 20 (on-cell configuration with LCD-type screen), 21 (on-cell configuration with an OLED-type screen), 22 (in-cell configuration with LCD-type screen) and 23 (in-cell configuration with an OLED-type screen):
the command switches 1805.2 are arranged so as either to connect the command lines 1300 (for LCD-type screen) or 1400 (for OLED-type screens) to the display control electronics 1109 during the display control phases, or to keep them electrically floating (in an open circuit) during the capacitance measurement phases;
the data switches 1805.1 are arranged so as either to connect the data lines 1301 (for LCD-type screen) or 1401 (for OLED-type screens) to the display control electronics 1109 during the display control phases, or to keep them electrically floating (in an open circuit) during the capacitance measurement phases;

In this variant, the command switches 1805.2 and the data switches 1805.1 are therefore in the open position during the capacitance measurement phases. The command lines 1300 or 1400 and the data lines 1301 or 1401 are then electrically floating, and since they are strongly capacitively coupled to the common potential layer 1104 at the guard potential 1103, they tend to polarize to that common potential 1104. As before, the parasitic capacitance present between the gate and the source of the TFT transistors that command pixels serves to keep them in blocked mode for a sufficient duration to cover the capacitance measurement phase.

Simpler assemblies are possible with these implementation variants of command switches 1805.2 and data switches 1805.1, but with a greater risk of generating parasitic couplings with the measurement electrodes 502 during capacitance measurements. Furthermore, since the command lines 1300 or 1400 are floating, a risk of the TFT transistors of the pixels becoming turned on during the capacitance measurements may appear, which could result in a variation in the light intensity of the pixels. However, this risk is low, due to the memory effect of the parasitic capacitances of the TFT transistors.

They may thus validly be implemented in particular in on-cell configurations (FIGS. 20 and 21) with an AMLCD or AMOLED screen in which the capacitance measurement electrodes 502 on the one hand, and the command layer 1102 with an electrode 210 of the pixels on the other hand, are positioned on either side of the common potential layer 1104 that thus produces effective shielding (in so far as it does not include too many openings).

Of course, the invention is not limited to the examples which were just described and many improvements can be made to these examples without going outside the scope of the invention.

1. A human-machine interface device comprising:
a display with display pixels distributed in a display area;
display control elements arranged in said display area and used for controlling said display pixels;
capacitive measurement electrodes distributed in said display area;
capacitive means of excitation and detection suited for (i) exciting the capacitive measurement electrodes to an alternating electric potential for excitation with at least one excitation frequency; and (ii) detecting the presence of command objects in a neighborhood of said capacitive measurement electrodes, on a viewing surface of the display by capacitive coupling between said capacitive measurement electrodes and the one or more command objects; and
at least one guard element arranged near the capacitive measurement electrodes in a layer separate from the capacitive measurement electrodes and the display control elements, and polarized to a guard potential identical or substantially identical to the excitation potential at the one or more excitation frequencies;
wherein at least one display control element is also used as a guard element or as a capacitance measurement electrode.

2. The device according to claim 1, wherein at least one of a portion of the display and the display control elements is electrically referenced to a reference potential corresponding to the guard potential, at least during a capacitance measurement phase.

3. The device according to claim 1, the capacitive measurement electrodes incorporated in an upper layer of capacitive electrodes, arranged towards the viewing surface relative to the constituent layers of the display pixels.

4. The device according to claim 3, comprising guard elements integrated into a common potential layer of the display control elements shared with at least one part of the display pixels.

5. The device according to claim 1, the capacitive measurement electrodes integrated into a common potential layer of the display control elements shared with at least one part of the display pixels.

6. The device according to claim 5, the common potential layer arranged in the form of an electrode matrix, and means of switching with which to connect the capacitive measurement electrodes either to capacitive means of detection or to a reference potential.

7. The device according to claim 5, wherein the at least one guard element located in the layer separate from the capacitive measurement electrodes and the display control elements comprises a lower guard layer, arranged opposite the viewing surface relative to the constituent layers of the display pixels.

8. The device according to claim 1, further comprising a display with liquid crystal elements.

9. The device according to claim 8, comprising a common potential layer with the capacitive measurement electrodes and a command layer with transistors configurable for controlling the liquid crystal elements arranged opposite the common potential layer relative to the viewing surface.

10. The device according to claim 9, comprising an IPS type display with command electrodes for the liquid crystal elements arranged in a plane towards the viewing surface relative to the common potential layer, said device further comprising means of switching with which to electrically isolate the command electrodes such that they are electrically floating during capacitance measurements.

11. The device according to claim 1, further comprising a display with organic light-emitting diodes (OLED).

12. The device according to claim 11, further comprising a common potential layer with the capacitive measurement-electrodes, and a command layer with transistors suited for controlling the organic light-emitting diodes arranged opposite the common potential layer relative to the viewing surface.

13. The device according to claim 9, the capacitive measurement electrodes having openings across from the command layer transistors so as to limit the coupling capacitances between these elements.

14. The device according to claim 9, further comprising a lower guard layer arranged across from the command layer relative to the viewing surface.

15. The device according to claim 1, further comprising capacitive detection means with at least one charge amplifier.

16. The device according to claim 15, wherein the capacitive detection means further comprise switches arranged so as to connect, at least during a capacitance measurement phase, the capacitive measurement electrodes either to at least one charge amplifier or to the guard potential.

17. (canceled)

18. The device according to claim 1, wherein the capacitive detection means are at least in part referenced to the guard potential.

19. (canceled)

20. The device according to claim 1, further comprising display control electronics referenced to earth ground, and a switching module with which to configure display control elements arranged in the display zone, including at least one command layer and one common potential layer such that said display control elements are referenced to:
the earth ground during the display refresh phases;
the guard potential, directly or by capacitive coupling, during the capacitance measurement phases.

21-31. (canceled)
